(19) United States
(12) Patent Application Publication
(10) Pub. No.: US 2024/0114734 A1
(43) Pub. Date: Apr. 4, 2024

(54) DISPLAY DEVICE, ELECTRONIC DEVICE INCLUDING THE SAME

(71) Applicant: Samsung Display Co., LTD., Yongin-si (KR)

(72) Inventors: JAYBUM KIM, Yongin-si (KR); MYEONGHO KIM, Yongin-si (KR); Youngoo KIM, Yongin-si (KR); KYOUNG SEOK SON, Yongin-si (KR); SUNGHOON YANG, Yongin-si (KR); SUNHEE LEE, Yongin-si (KR); SEUNGHUN LEE, Yongin-si (KR)

(21) Appl. No.: 18/234,778

(22) Filed: Aug. 16, 2023

(30) Foreign Application Priority Data
Sep. 30, 2022 (KR) 10-2022-0124899

(51) Int. Cl. H10K 59/131; H10K 59/124

(52) U.S. Cl. CPC H10K 59/131; H10K 59/124

(57) ABSTRACT

A display device includes a first pixel and a second pixel. The light emitting element of the second pixel and the driving circuit are disposed in the second area. The first pixel includes a silicon transistor and an oxide transistor disposed in the second area. The first pixel includes a first sub-light emitting element and a second sub-light emitting element disposed in a first area, and a first sub-pixel circuit and a second sub-pixel circuit disposed in a second area. A first connection wiring connecting a transistor included in the first sub-pixel circuit and the first sub-light emitting element, and a second connection wiring connecting a transistor included in the second sub-pixel circuit and the second sub-light emitting element are disposed on different layers and include a transparent conductive oxide.

### CROSS-REFERENCE TO RELATED APPLICATIONS

The present application claims priority to and the benefit of Korean Patent Application No. 10-2022-0124899, filed on Sep. 30, 2022, the entire content of which is hereby incorporated by reference.

### BACKGROUND

Aspects of some embodiments of the inventive concept relate to a display device including a display area through which an optical signal passes, and an electronic device including the display device.

An electronic device may include various electronic components such as a display panel and an electronic module. The electronic module may include a camera, an infrared sensor, or a proximity sensor. The electronic module may be located under the display panel. Transmittance of some areas of the display panel may be relatively higher than transmittance of other partial areas of the display panel. The electronic module may receive an optical signal or output an optical signal through an area having relatively high transmittance.

The above information disclosed in this Background section is only for enhancement of understanding of the background and therefore the information discussed in this Background section does not necessarily constitute prior art.

### SUMMARY

Aspects of some embodiments of the inventive concept include a display device having a relatively simplified laminated structure.

Aspects of some embodiments of the inventive concept may also include an electronic device including a display device having a relatively simplified laminated structure.

Aspects of some embodiments of the inventive concept provides a display device including: a display area including a first area and a second area adjacent to the first area; and a display panel including a base layer including a peripheral area adjacent to the display area, an insulating layer disposed on the base layer, and a first pixel and a second pixel disposed on the base layer, wherein the first pixel includes a first sub-pixel and a second sub-pixel that are different from each other, wherein the first sub-pixel includes a first sub-light emitting element disposed in the first area and a first sub-pixel circuit electrically connected to the first sub-light emitting element, wherein the second sub-pixel includes a second sub-light emitting element disposed in the first area and a second sub-pixel circuit electrically connected to the second sub-light emitting element, wherein the second pixel includes a second light emitting element disposed in the second area and a second pixel circuit electrically connected to the second light emitting element and disposed in the second area, wherein the first sub-pixel circuit includes: a first silicon transistor including a first silicon semiconductor pattern including a drain area, an active area, and a source area and a first gate electrode overlapping the active area of the first silicon semiconductor pattern, and disposed in the second area or the peripheral area; a first oxide transistor including a first oxide semiconductor pattern including a drain area, an active area, and a source area and a second gate electrode overlapping the active area of the first oxide semiconductor pattern, and disposed in the second area or the peripheral area; a first upper electrode overlapping the first gate electrode; and a first connection wiring electrically connecting the first silicon transistor or the first oxide transistor and the first sub-light emitting element, overlapping the first area, disposed on the same layer as the first upper electrode, and including a transparent conductive oxide, wherein the second sub-pixel circuit includes: a second silicon transistor including a second silicon semiconductor pattern including a drain area, an active area, and a source area and a third gate electrode overlapping the active area of the second silicon semiconductor pattern, and disposed in the second area or the peripheral area; a second oxide transistor including a second oxide semiconductor pattern including a drain area, an active area, and a source area and a fourth gate electrode overlapping the active area of the second oxide semiconductor pattern, and disposed in the second area or the peripheral area; a second upper electrode overlapping the third gate electrode; and a second connection wiring electrically connecting the second silicon transistor or the second oxide transistor and the second sub-light emitting element, overlapping the first area, disposed on the same layer as the second oxide semiconductor pattern, and including a transparent conductive oxide.

According to some embodiments, the insulating layer may include: a lower insulating layer under the first upper electrode and the second upper electrode; and an upper insulating layer on the first upper electrode and the second upper electrode.

According to some embodiments, the first and second oxide semiconductor patterns and the second connection wiring may be on the upper insulating layer.

According to some embodiments, the upper insulating layer may cover the first connection wiring, the first upper electrode, and the second upper electrode.

According to some embodiments, the display device may further include insulating patterns disposed between the active area of the first oxide semiconductor pattern and the second gate electrode and between the active area of the second oxide semiconductor pattern and the fourth gate electrode, respectively.

According to some embodiments, the insulating layer may be disposed on the upper insulating layer and may further include a cover insulating layer covering the first and second oxide semiconductor patterns and the second connection wiring.

According to some embodiments, the cover insulating layer may have an opening corresponding to the first area, wherein a portion of the second connection wiring may be exposed by the opening defined in the cover insulating layer.

According to some embodiments, the first connection wiring, the second connection wiring, the first and second upper electrodes, and the first and second oxide semiconductor patterns each may include at least one of In, Zn, and Sn.

According to some embodiments, the display area may further include a third area adjacent to the second area, wherein the display panel may further include a third pixel disposed in the third area, wherein the third pixel may include a third light emitting element disposed in the third area and a third pixel circuit electrically connected to the third light emitting element and disposed in the third area, wherein the number of second light emitting elements disposed per unit area of the second area may be less than the number of third light emitting elements disposed per unit area of the third area, wherein a sum of the numbers of the first sub-light emitting elements and the second sub-light emitting elements disposed per unit area of the first area may be less than the number of third light emitting elements disposed per unit area of the third area.

According to some embodiments, an electrical conductivity of the second connection wiring is greater than an electrical conductivity of the active area of the first and second oxide semiconductor patterns.

According to some embodiments of the inventive concept, a display device includes: a display area including a first area, a second area adjacent to the first area, and a third area adjacent to the second area; and a display panel including a base layer including a peripheral area adjacent to the display area, an insulating layer disposed on the base layer, and first to third pixels disposed on the base layer, wherein the first pixel includes a first sub-pixel and a second sub-pixel that are different from each other, wherein the first sub-pixel includes a first sub-light emitting element disposed in the first area and a first sub-pixel circuit electrically connected to the first sub-light emitting element, wherein the second sub-pixel includes a second sub-light emitting element disposed in the first area and a second sub-pixel circuit electrically connected to the second sub-light emitting element, wherein the second pixel includes a second light emitting element disposed in the second area and a second pixel circuit electrically connected to the second light emitting element and disposed in the second area, wherein the third pixel includes a third light emitting element disposed in the third area and a third pixel circuit electrically connected to the third light emitting element, wherein a sum of the numbers of the first sub-light emitting elements and the second sub-light emitting elements disposed per unit area of the first area is less than the number of the third light emitting elements disposed per unit area of the third area, wherein the number of second light emitting elements disposed per unit area in the second area is less than the number of third light emitting elements disposed per unit area in the third area, wherein the first sub-pixel circuit includes: a first silicon transistor including a first silicon semiconductor pattern including a drain area, an active area, and a source area and a first gate electrode overlapping the active area of the first silicon semiconductor pattern, and disposed in the second area or the peripheral area; a first oxide transistor including a first oxide semiconductor pattern including a drain area, an active area, and a source area and a second gate electrode overlapping the active area of the first oxide semiconductor pattern, and disposed in the second area or the peripheral area; a first upper electrode overlapping the first gate electrode; and a first connection wiring electrically connecting the first silicon transistor or the first oxide transistor and the first sub-light emitting element, overlapping the first area, disposed on the same layer as the first upper electrode, and including a transparent conductive oxide, wherein the second sub-pixel circuit includes: a second silicon transistor including a second silicon semiconductor pattern including a drain area, an active area, and a source area and a third gate electrode overlapping the active area of the second silicon semiconductor pattern, and disposed in the second area or the peripheral area; a second oxide transistor including a second oxide semiconductor pattern including a drain area, an active area, and a source area and a fourth gate electrode overlapping the active area of the second oxide semiconductor pattern, and disposed in the second area or the peripheral area; a second upper electrode overlapping the third gate electrode; and a second connection wiring electrically connecting the second silicon transistor or the second oxide transistor and the second sub-light emitting element, overlapping the first area, disposed on a layer different from the first connection wiring, and including a transparent conductive oxide

According to some embodiments, the insulating layer may include: a lower insulating layer under the first upper electrode and the second upper electrode; and an upper insulating layer on the first upper electrode and the second upper electrode.

According to some embodiments, the first and second upper electrodes and the first and second oxide semiconductor patterns may be disposed on the same layer on the lower insulating layer, wherein the first and second upper electrodes and the first and second oxide semiconductor patterns may be covered by the upper insulating layer.

According to some embodiments, the display device may further include a first insulating pattern disposed between the active area of the first oxide semiconductor pattern and the second gate electrode and between the active area of the second oxide semiconductor pattern and the fourth gate electrode, and a second insulating pattern disposed between the lower insulating layer and the second connection wiring.

According to some embodiments, the first connection wiring, the second connection wiring, the first upper electrode, the second upper electrode, the first oxide semiconductor pattern, the second oxide semiconductor pattern, the second gate electrode, and the fourth gate electrode each may include at least one of In, Zn, and Sn.

According to some embodiments of the inventive concept, an electronic device includes: a display device including a sensing area through which an optical signal passes, a display area adjacent to the sensing area, and a peripheral area adjacent to the display area, wherein the sensing area includes an element area overlapped by a first light emitting element including a first sub-light emitting element and a second sub-light emitting element, and a transmissive area non-overlapped by the first light emitting element; and an electronic module disposed below the display device, overlapping the sensing area, and receiving the optical signal, wherein the display device includes: a first sub-light emitting element disposed in the element area and a first sub-pixel electrically connected to the first sub-light emitting element; and a second sub-light emitting element disposed in the element area, and a second sub-pixel electrically connected to the second sub-light emitting element, wherein the first sub-pixel circuit includes: a first transistor including a first silicon semiconductor pattern including a drain area, an active area, and a source area and a first gate electrode overlapping the active area of the first silicon semiconductor pattern, and disposed in the display area or the peripheral area; a second transistor including a first oxide semiconductor pattern including a drain area, an active area, and a source area and a second gate electrode overlapping the active area of the first oxide semiconductor pattern, and disposed in the display area or the peripheral area; a first upper electrode overlapping the first gate electrode; and a first connection wiring electrically connecting the first or second transistor and the first sub-light emitting element, overlapping the sensing area, and disposed on the same layer as the first upper electrode, and including a transparent conductive oxide, wherein the second sub-pixel circuit includes: a third transistor including a second silicon semiconductor pattern including a drain area, an active area, and a source area and a third gate electrode overlapping the active area of the second silicon semiconductor pattern, and disposed in the display area or the peripheral area; a fourth transistor including a second oxide semiconductor pattern including a drain area, an active area, and a source area and a fourth gate electrode overlapping the active area of the second oxide semiconductor pattern, and disposed in the display area or the peripheral area; a second upper electrode overlapping the third gate electrode; and a second connection wiring electrically connecting the third transistor or the fourth transistor and the second sub-light emitting element, overlapping the sensing area and disposed on the same layer as the second oxide semiconductor pattern, and including a transparent conductive oxide.

According to some embodiments, the display device may further include a display pixel including a second light emitting element disposed in the display area and a second pixel circuit electrically connected to the second light emitting element and disposed in the display area, wherein a sum of the numbers of the first sub-light emitting elements and the second sub-light emitting elements per unit area disposed in the sensing area may be less than the number of second light emitting elements disposed per unit area in the display area.

According to some embodiments, the electronic module may include a camera module.

According to some embodiments, an electrical conductivity of the second connection wiring may be greater than each electrical conductivity of the active area of the first oxide semiconductor pattern and the active area of the second oxide semiconductor pattern.

According to some embodiments, the display device may further include a window, wherein the window may include a base film and a bezel pattern disposed on the base film and overlapping the peripheral area.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an electronic device according to some embodiments;

FIG. 2 is an exploded perspective view illustrating some components of an electronic device according to some embodiments;

FIG. 3 is a cross-sectional view of a display device according to some embodiments;

FIG. 4 is an equivalent circuit diagram of a pixel according to some embodiments;

FIG. 5A is a plan view of a display panel according to some embodiments;

FIG. 5B is an enlarged plan view of a portion of FIG. 5A;

FIG. 5C is an enlarged plan view of a portion of FIG. 5B;

FIG. 5D is an enlarged plan view of a part of FIG. 5B;

FIG. 5E is a plan view of a display panel according to some embodiments;

FIG. 6 is a cross-sectional view corresponding to a third area of a display device according to some embodiments;

FIG. 7A is a cross-sectional view corresponding to a first area and a second area of a display device according to some embodiments;

FIG. 7B is a cross-sectional view corresponding to a first area and a second area of a display device according to some embodiments;

FIG. 8 is a cross-sectional view corresponding to a first area and a second area of a display device according to some embodiments; and

FIG. 9 is a cross-sectional view corresponding to a first area and a second area of a display device according to some embodiments.

### DETAILED DESCRIPTION

Because the inventive concept may have various changes and may have various forms, specific embodiments are illustrated in the drawings and described in detail in the text. However, this is not intended to limit the inventive concept to specific embodiments, and should be understood to include all modifications, equivalents and substitutes included in the spirit and scope of the inventive concept.

In this specification, when an element (or region, layer, part, etc.) is referred to as being “on”, “connected to”, or “coupled to” another element, it means that it may be directly placed on/connected to/coupled to other components, or a third component may be arranged between them.

Meanwhile, in the present specification, “directly located” or “directly contacting” may mean that there is no layer, film, region, plate, and the like added between a portion such as a layer, film, region, or plate and another portion. For example, “directly located” or “directly contacting” may mean arranging between two layers or two members without using an additional member such as an adhesive member.

Like reference numerals refer to like elements. Additionally, in the drawings, the thicknesses, proportions, and dimensions of components are exaggerated for effective description.

“And/or” includes all of one or more combinations defined by related components.

It will be understood that the terms “first” and “second” are used herein to describe various components but these components should not be limited by these terms. The above terms are used only to distinguish one component from another. For example, a first component may be referred to as a second component and vice versa without departing from the scope of the inventive concept. The terms of a singular form may include plural forms unless otherwise specified.

In addition, terms such as “below”, “the lower side”, “on”, and “the upper side” are used to describe a relationship of configurations shown in the drawing. The terms are described as a relative concept based on a direction shown in the drawing. In the present specification, “located on” may refer to a case of being located not only on the upper part of any one member but also on the lower part.

Unless otherwise defined, all terms (including technical and scientific terms) used herein have the same meaning as commonly understood by one of ordinary skill in the art to which this inventive concept belongs. In addition, terms such as terms defined in commonly used dictionaries should be interpreted as having a meaning consistent with the meaning in the context of the related technology, and it should not be construed in an overly ideal or overly formal sense unless explicitly defined here.

In various embodiments of the inventive concept, the term “include,” “comprise,” “including,” or “comprising,” specifies a property, a region, a fixed number, a step, a process, an element and/or a component but does not exclude other properties, regions, fixed numbers, steps, processes, elements and/or components.

Hereinafter, a display device and an electronic device including the display device according to some embodiments will be described with reference to the drawings.

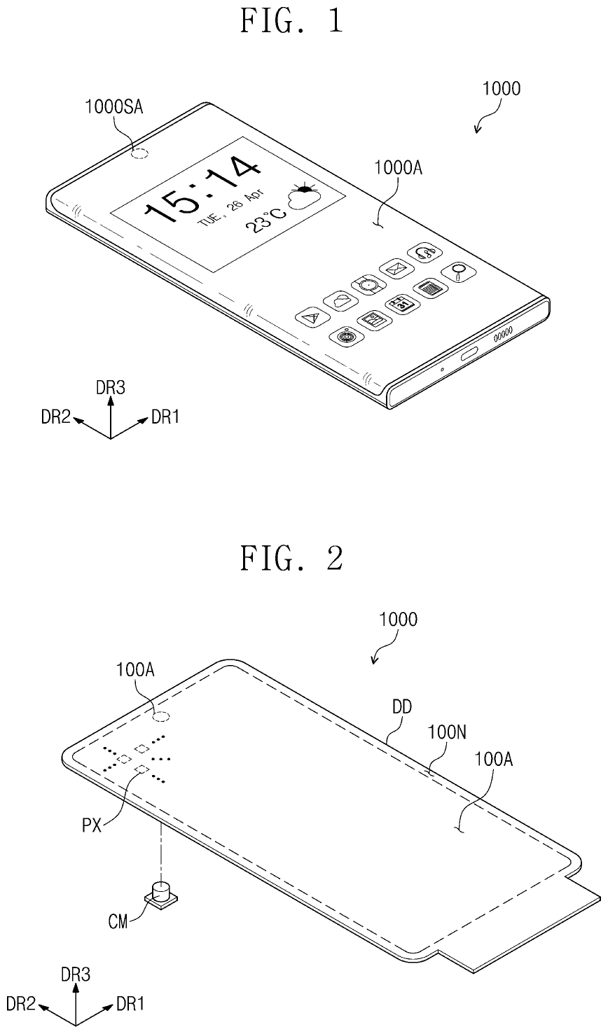

FIG. 1 is a perspective view of an electronic device 1000 according to some embodiments.

Referring to FIG. 1, the electronic device 1000 may include a display device, and a mobile phone is illustrated as an example, but embodiments according to the present disclosure are not limited thereto. However, the embodiments of the inventive concept are not limited thereto, and the electronic device 1000 may be a tablet, a monitor, a television, a car navigation system, a game machine, a wearable device, or any other electronic device having a display panel utilized therein.

The electronic device 1000 may display images through the display area 1000A. The display area 1000A may include a plane defined by the first direction DR1 and the second direction DR2. The display area 1000A may further include curved surfaces each bent from at least two sides of the plane. However, the shape of the display area 1000A is not limited thereto. For example, the display area 1000A may include only the plane, and the display area 1000A may further include at least two or more, for example, four curved surfaces each bent from four sides of the plane.

A part of the display area 1000A may be defined as a sensing area 1000SA. Although one sensing area 1000SA is illustrated in FIG. 1 as an example, the number of sensing areas 1000SA is not limited thereto. The sensing area 1000SA may be a part of the display area 1000A, but may have higher optical signal transmittance than other areas of the display area 1000A. Accordingly, images may be displayed through the sensing area 1000SA, and optical signals may be provided or transmitted through the sensing area 1000SA.

The electronic device 1000 may include an electronic module located in an area overlapping the sensing area 1000SA. The electronic module may receive an optical signal provided from the outside through the sensing area 1000SA or output an optical signal through the sensing area 1000SA. For example, the electronic module may be a camera module, a sensor that measures distance between an object and a mobile phone, such as a proximity sensor, a sensor that recognizes a part of the user's body (e.g., fingerprint, iris, or face), or a small lamp that outputs light, but is not particularly limited thereto.

The thickness direction of the electronic device 1000 may be the third direction DR3, which is a normal direction of the display area 1000A. The front (or upper) and rear (or lower) surfaces of the members constituting the electronic device 1000 may be defined with respect to the third direction DR3.

FIG. 2 is an exploded perspective view illustrating some components of an electronic device 1000 according to some embodiments.

Referring to FIG. 2, the electronic device 1000 may include a display device DD and a camera module CM. The display device DD may generate images and sense an external input. The camera module CM is located below the display device DD. When the display device DD is defined as a first electronic module constituting the electronic device 1000, the camera module CM may be defined as a second electronic module.

The display device DD may include a display area 100A and a peripheral area 100N. The display area 100A may correspond to the display area 1000A shown in FIG. 1. A partial area of the display device DD may be defined as a sensing area 100SA, and the sensing area 100SA may have a higher transmittance than other areas (hereinafter, main display areas) of the display area 100A. Accordingly, the sensing area 100SA may provide external natural light to the camera module CM. Because the sensing area 100SA is a part of the display area 100A, an image may be displayed.

A pixel PX is located in the display area 100A. A light emitting element is located in the display area 100A, and a light emitting element is not located in the peripheral area 100N. Pixels PX are respectively located in the sensing area 100SA and the main display area. However, configurations of the pixels PX located in the sensing area 100SA and the main display area may be different. A detailed description of this will be described in more detail later.

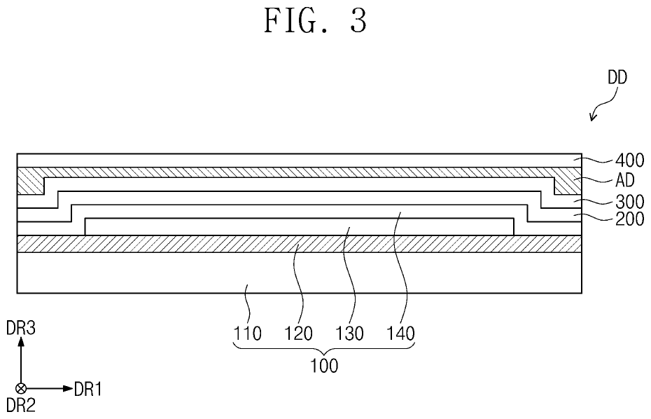

FIG. 3 is a cross-sectional view of a display device DD according to some embodiments.

Referring to FIG. 3, the display device DD may include a display panel 100, a sensor layer 200 and an anti-reflection layer 300, and a window 400. The anti-reflection layer 300 and the window 400 may be combined with an adhesive layer AD. However, this is only an example, and the embodiments according to the present disclosure are not limited thereto, and the window 400 may be directly located on the anti-reflection layer 300.

The display panel 100 may be configured to substantially generate an image. The display panel 100 may be a light emitting display panel, and for example, the display panel 100 may be an organic light emitting display panel, an inorganic light emitting display panel, a micro LED display panel, or a nano LED display panel. The display panel 100 may also be referred to as a display layer.

The display panel 100 may include a base layer 110, a circuit layer 120, a light emitting element layer 130, and an encapsulation layer 140.

The base layer 110 may be a member that provides a base surface on which the circuit layer 120 is located. The base layer 110 may be a rigid substrate or a flexible substrate capable of bending, folding, rolling, or the like. The base layer 110 may be a glass substrate, a metal substrate, or a polymer substrate. However, embodiments of the inventive concept are not limited thereto, and the base layer 110 may include an inorganic layer, an organic layer, or a composite material layer.

The base layer 110 may have a multilayer structure. For example, the base layer 110 may include a first synthetic resin layer, a multi- or single-layer inorganic layer, and a second synthetic resin layer located on the multi- or single-layer inorganic layer. Each of the first and second synthetic resin layers may include a polyimide-based resin, and is not particularly limited.

The circuit layer 120 may be located on the base substrate 110. The circuit layer 120 may include an insulating layer, a semiconductor pattern, a conductive pattern, and a signal line.

The light emitting element layer 130 may be located on the circuit layer 120. The light emitting element layer 130 may include a light emitting element. For example, the light emitting element may include an organic light emitting material, an inorganic light emitting material, an organic-inorganic light emitting material, a quantum dot, a quantum rod, a micro LED, or a nano LED.

The encapsulation layer 140 may be located on the light emitting element layer 130. The encapsulation layer 140 may protect the light emitting element layer 130 from foreign substances such as moisture, oxygen, and dust particles. The encapsulation layer 140 may include at least one inorganic layer. The encapsulation layer 140 may include a stacked structure of inorganic layers/organic layers/inorganic layers.

The sensor layer 200 may be located on the display panel 100. The sensor layer 200 may detect an external input applied from the outside. The external input may be a user's input. The user's input may include various types of external inputs such as a part of the user's body (e.g., a finger), light, heat, pen (e.g., a stylus), or pressure.

The sensor layer 200 may be formed on the display panel 100 through a continuous process. In this case, the sensor layer 200 may be directly located on the display panel 100. Here, “directly located” may mean that a third component is not located between the sensor layer 200 and the display panel 100. That is, a separate adhesive member may not be located between the sensor layer 200 and the display panel 100.

The anti-reflection layer 300 may be directly located on the sensor layer 200. The anti-reflection layer 300 may reduce reflectance of external light incident from the outside of the display device DD. The anti-reflection layer 300 may be formed on the sensor layer 200 through a continuous process. The anti-reflection layer 300 may include color filters. The color filters may have an arrangement (e.g., a set or predetermined arrangement). For example, the color filters may be arranged in consideration of emission colors of pixels included in the display panel 100. In addition, the anti-reflection layer 300 may further include a black matrix adjacent to the color filters.

According to some embodiments, the sensor layer 200 may be omitted. In this case, the anti-reflection layer 300 may be directly located on the display panel 100. According to some embodiments, the positions of the sensor layer 200 and the anti-reflection layer 300 may be interchanged.

According to some embodiments, the display device DD may further include an optical layer located on the anti-reflection layer 300. For example, the optical layer may be formed on the anti-reflection layer 300 through a continuous process. The optical layer may improve front luminance of the display device DD by controlling a direction of light incident from the display panel 100. For example, the optical layer may include an organic insulating layer in which openings are defined, and a high refractive index layer covering the organic insulating layer and filling the openings, corresponding to emission areas of pixels included in the display panel 100, respectively. The high refractive index layer may have a higher refractive index than the organic insulating layer.

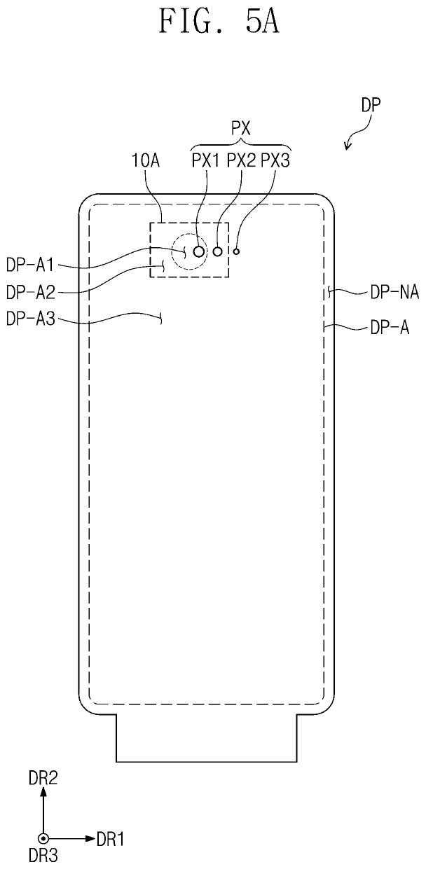

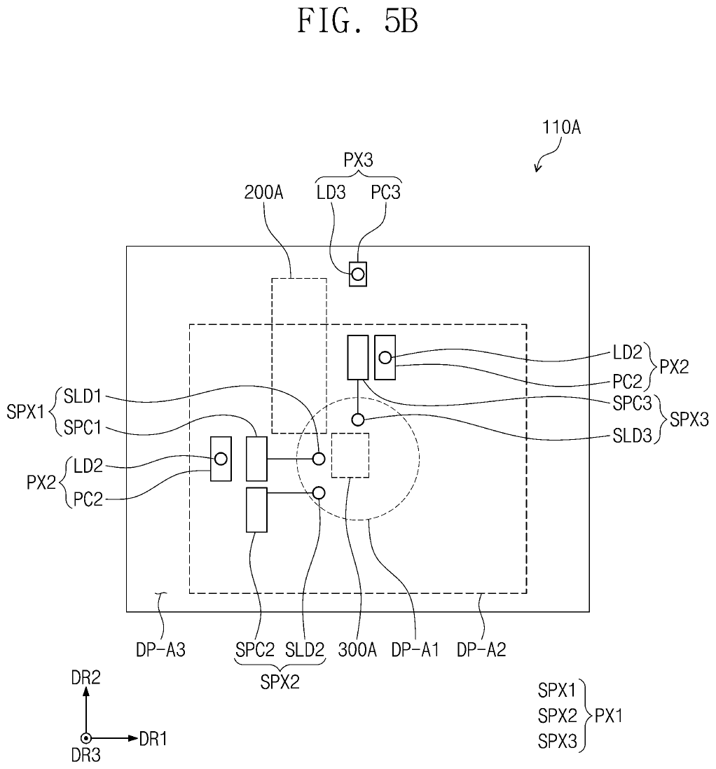

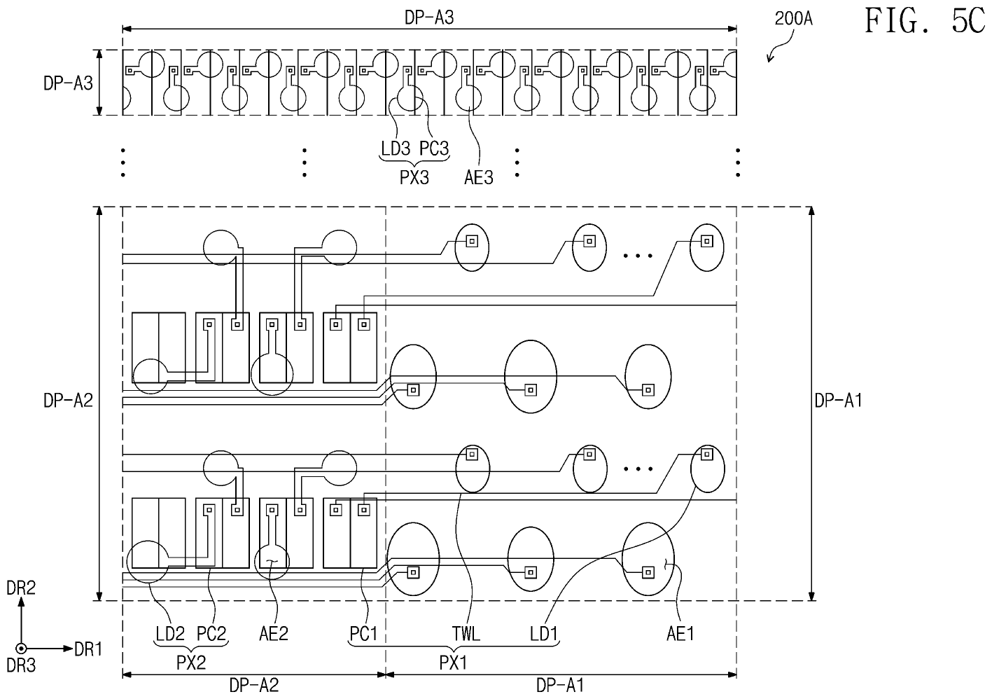

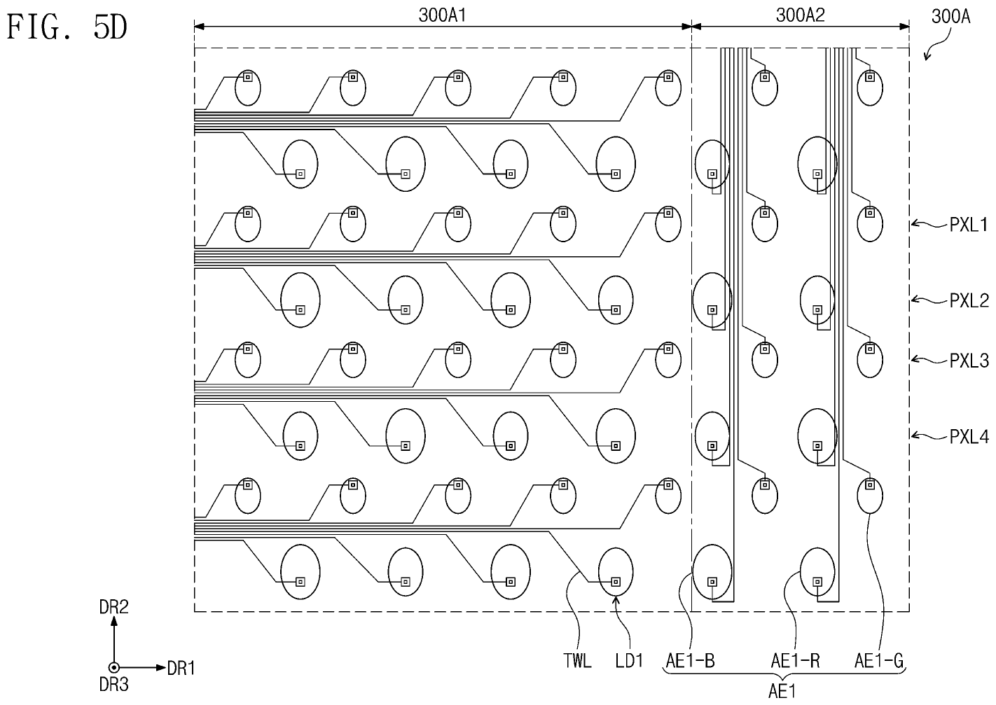

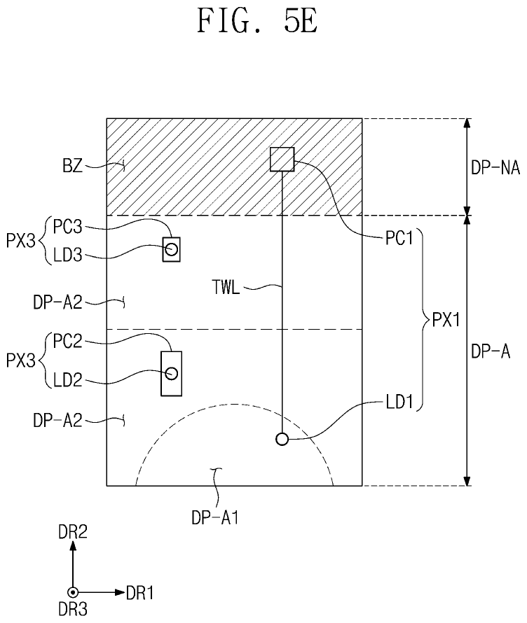

The window 400 may provide a front surface of the electronic device 1000. The window 400 may include a glass film or synthetic resin film as a base film. The window 400 may further include an anti-reflection layer or an anti-fingerprint layer. The window 400 may include a glass film or synthetic resin film. The window 400 may further include a bezel pattern BZ (see FIG. 5E) overlapping the peripheral area DP-NA of the display panel 100.

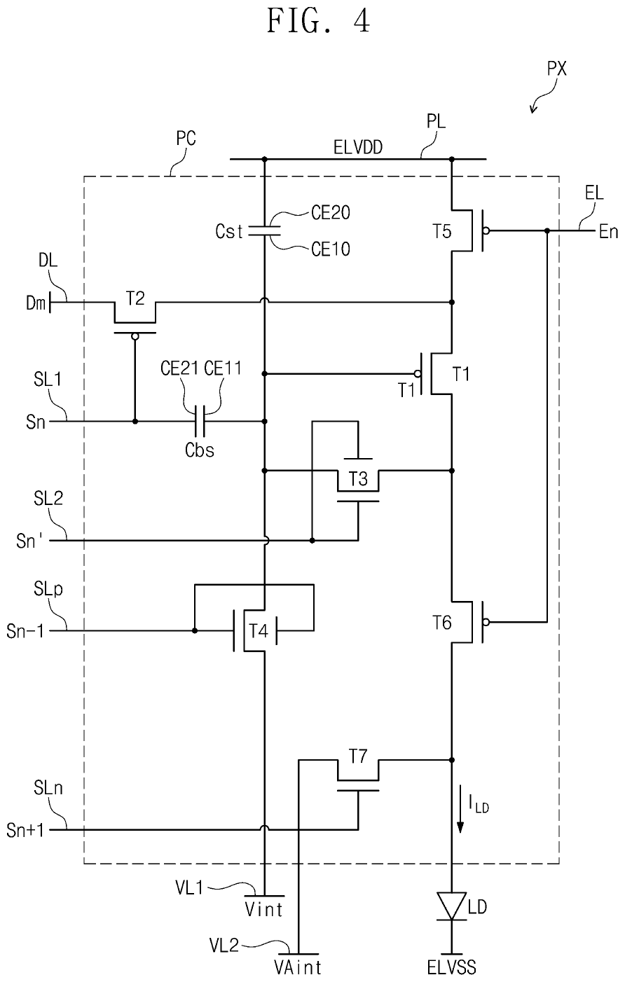

FIG. 4 is an equivalent circuit diagram of a pixel PX according to some embodiments.

Referring to FIG. 4, an equivalent circuit diagram of one pixel PX among the plurality of pixels PX shown in FIG. 2 is shown. The pixel PX may include a light emitting element LD and a pixel circuit PC. The light emitting element LD may be a component included in the light emitting element layer 130 of FIG. 3, and the pixel circuit PC may be a component included in the circuit layer 120 of FIG. 3.

The pixel circuit PC may include a plurality of transistors T1 to T7 (or thin film transistors) and a storage capacitor Cst. The plurality of transistors T1 to T7 and the storage capacitor Cst may be electrically connected to the signal lines SL1, SL2, SLp, SLn, EL, and DL, the first initialization voltage line VL1, the second initialization voltage line VL2 (or the anode initialization voltage line), and the driving voltage line PL.

The plurality of transistors T1 to T7 may include a driving transistor T1 (or first transistor), a switching transistor T2 (or second transistor), a compensation transistor T3 (or third transistor), a first initialization transistor T4 (or fourth transistor), an operation control transistor T5 (or fifth transistor), an emission control transistor T6 (or sixth transistor), and a second initialization transistor T7 (or seventh transistor).

The light emitting element LD may include a first electrode (e.g., an anode electrode or a pixel electrode) and a second electrode (e.g., a cathode electrode or a common electrode), and the first electrode of the light emitting element LD is connected to the driving transistor T1 through the emission control transistor T6 to receive the driving current ILD, and the second electrode may receive a low power supply voltage ELVSS. The light emitting element LD may generate light having a luminance corresponding to the driving current ILD.

Some of the plurality of transistors T1 to T7 may be n-channel MOSFETs (NMOS), and others may be p-channel MOSFETs (PMOS). For example, among the plurality of transistors T1 to T7, the compensation transistor T3 and the first initialization transistor T4 may be n-channel MOSFETs (NMOS), and the others may be p-channel MOSFETs (PMOS).

According to some embodiments, among the plurality of transistors T1 to T7, the compensation transistor T3, the first initialization transistor T4, and the second initialization transistor T7 may be NMOS, and the others may be PMOS. According to some embodiments, only one of the plurality of transistors T1 to T7 may be NMOS, and the others may be PMOS. According to some embodiments, all of the plurality of transistors T1 to T7 may be NMOS or all PMOS.

Signal lines may include a first current scan line SL1 transmitting the first scan signal Sn, a second current scan line SL2 transmitting the second scan signal Sn′; a prior scan line SLp transmitting the prior scan signal Sn−1 to the first initialization transistor T4, an emission control line EL transmitting an emission control signal En to the operation control transistor T5 and the emission control transistor T6, a next scan line SLn transmitting the next scan signal Sn+1 to the second initialization transistor T7, and a data line DL crossing the first current scan line SL1 and transmitting the data signal Dm.

The driving voltage line PL may transmit the driving voltage ELVDD to the driving transistor T1, and the first initialization voltage line VL1 may transmit the initialization voltage Vint1 for initializing the driving transistor T1 and the first electrode of the light emitting element LD.

The gate of the driving transistor T1 may be connected to the storage capacitor Cst, the source of the driving transistor T1 may be connected to the driving voltage line PL via the operation control transistor T5, and the drain of the driving transistor T1 may be electrically connected to the first electrode of the light emitting element LD via the emission control transistor T6. The driving transistor T1 may receive the data signal Dm according to the switching operation of the switching transistor T2 and supply the driving current ILD to the light emitting element LD.

The gate of the switching transistor T2 may be connected to the first current scan line SL1 transmitting a first scan signal Sn, the source of the switching transistor T2 may be connected to the data line DL, and the drain of the switching transistor T2 may be connected to the driving voltage line PL via the operation control transistor T5 while being connected to the source of the driving transistor T1. The switching transistor T2 is turned on according to the first scan signal Sn transmitted through the first current scan line SL1 such that a switching operation of transferring the data signal Dm transmitted through the data line DL to the source of the driving transistor T1 may be performed.

A gate of the compensation transistor T3 is connected to the second current scan line SL2. The drain of the compensation transistor T3 may be connected to the first electrode of the light emitting element LD via the emission control transistor T6 while being connected to the drain of the driving transistor T1. A source of the compensation transistor T3 may be connected to the first electrode CE10 of the storage capacitor Cst and the gate of the driving transistor T1. Also, a source of the compensation transistor T3 may be connected to a drain of the first initialization transistor T4.

The compensation transistor T3 is turned on according to the second scan signal Sn′ transmitted through the second current scan line SL2 such that the driving transistor T1 may be diode-connected by electrically connecting the gate and drain of the driving transistor T1.

A gate of the first initialization transistor T4 may be connected to the prior scan line SLp. A source of the first initialization transistor T4 may be connected to a source of the second initialization transistor T7 and the first initialization voltage line VL1. The drain of the first initialization transistor T4 may be connected to the first electrode CE10 of the storage capacitor Cst, the source of the compensation transistor T3, and the gate of the driving transistor T1. The first initialization transistor T4 is turned on according to the previous scan signal Sn−1 received through the prior scan line SLp such that an initialization operation may be performed to initialize the gate voltage of the driving transistor T1 by transferring the initialization voltage Vint1 to the gate of the driving transistor T1.

The gate of the operation control transistor T5 may be connected to the emission control line EL, the operation control source of the operation control transistor T5 may be connected to the driving voltage line PL, and the drain of the operation control transistor T5 may be connected to a source of the driving transistor T1 and a drain of the switching transistor T2.

The gate of the emission control transistor T6 may be connected to the emission control line EL, the emission control source of the emission control transistor T6 may be connected to the drain of the driving transistor T1 and the drain of the compensation transistor T3, and the drain of the emission control transistor T6 may be electrically connected to the drain of the second initialization transistor T7 and the first electrode of the light emitting element LD.

The operation control transistor T5 and the emission control transistor T6 are simultaneously turned on according to the emission control signal En transmitted through the emission control line EL and the driving voltage ELVDD is transmitted to the light emitting element LD so that the driving current ILD flows in the light emitting element LD.

The gate of the second initialization transistor T7 may be connected to the next scan line SLn, the drain of the second initialization transistor T7 may be connected to the drain of the emission control transistor T6 and the first electrode of the light emitting element LD, and the source of the second initialization transistor T7 may be connected to the second initialization voltage line VL2 to receive an anode initialization voltage Vint2. The second initialization transistor T7 is turned on according to the scan signal Sn+1 after being transmitted through the next scan line SLn to initialize the first electrode of the light emitting element LD.

According to some embodiments, the second initialization transistor T7 may be connected to the emission control line EL and driven according to the emission control signal En. Meanwhile, positions of the source and the drain may be interchanged depending on the type (p-type or n-type) of the transistor.

The storage capacitor Cst may include a first electrode CE10 and a second electrode CE20. The first electrode CE10 of the storage capacitor Cst is connected to the gate of the driving transistor T1, and the second electrode CE20 of the storage capacitor Cst is connected to the driving voltage line PL. A charge corresponding to a difference between the gate voltage of the driving transistor T1 and the driving voltage ELVDD may be stored in the storage capacitor Cst.

The boosting capacitor Cbs may include a first electrode CE11 and a second electrode CE21. The first electrode CE11 of the boosting capacitor Cbs may be connected to the first electrode CE11 of the storage capacitor Cst, and the second electrode CE21 of the boosting capacitor Cbs may receive the first scan signal Sn. The boosting capacitor Cbs increases the voltage of the gate of the driving transistor T1 at the time when the provision of the first scan signal Sn is stopped, so that the voltage drop of the gate may be compensated for.

Further detailed operation of each pixel PX according to some embodiments is described below.

During the initialization period, if the previous scan signal Sn−1 is supplied through the prior scan line SLp, the first initialization transistor T4 is turned on in response to the previous scan signal Sn−1, and the driving transistor T1 is initialized by the initialization voltage Vint1 supplied from the first initialization voltage line VL1.

During data programming, when the first scan signal Sn and the second scan signal Sn′ are supplied through the first current scan line SL1 and the second current scan line SL2, the switching transistor T2 and the compensation transistor T3 are turned on in response to the first scan signal Sn and the second scan signal Sn′. At this time, the driving transistor T1 is diode-connected by the turned-on compensation transistor T3 and biased in the forward direction.

Then, the compensation voltage (Dm+Vth, where Vth is a negative value) decreased by the threshold voltage Vth of the driving transistor T1 in the data signal Dm supplied from the data line DL is applied to the gate of the driving transistor T1.

A driving voltage ELVDD and a compensation voltage (Dm+Vth) are applied to both ends of the storage capacitor Cst, and a charge corresponding to a voltage difference between the two ends is stored in the storage capacitor Cst.

During the emission period, the operation control transistor T5 and the emission control transistor T6 are turned on by the emission control signal En supplied from the emission control line EL. A driving current ILD is generated according to a voltage difference between the voltage of the gate of the driving transistor T1 and the driving voltage ELVDD, and is supplied to the light emitting element LD through the emission control transistor T6.

According to some embodiments, at least one of the plurality of transistors T1 to T7 includes a semiconductor layer including oxide, and the others include a semiconductor layer including silicon.

For example, the driving transistor T1, which directly affects the brightness of the display device, is configured to include a semiconductor layer made of polycrystalline silicon having high reliability, thereby realizing a high-resolution display device.

On the other hand, because the oxide semiconductor has relatively high carrier mobility and relatively low leakage current, the voltage drop is not large even if the driving time is long. That is, because the color change of the image according to the voltage drop is not large even during low-frequency driving, low-frequency driving may be possible.

As such, in the case of an oxide semiconductor, because it has an advantage of relatively low leakage current, at least one of the compensation transistor T3, the first initialization transistor T4, or the second initialization transistor T7 connected to the gate of the driving transistor T1 is used as an oxide semiconductor such that leakage current that may flow to the gate may be prevented and power consumption may be reduced.

FIG. 5A is a plan view of a display panel DP according to some embodiments. FIG. 5B is an enlarged plan view of a portion 10A of FIG. 5A. FIG. 5C is an enlarged plan view of a portion 200A of FIG. 5B. FIG. 5D is an enlarged plan view of a portion 300A of FIG. 5B. FIG. 5E is a plan view of a display panel according to some embodiments.

Referring to FIG. 5A, the display panel 100 may include a display area DP-A and a peripheral area DP-NA. The peripheral area DP-NA is adjacent to the display area DP-A and may surround at least a portion of the display area DP-A. The peripheral area DP-NA may correspond to the peripheral area 100N of FIG. 3.

The display area DP-A may include a first area DP-A1, a second area DP-A2, and a third area DP-A3. The first area DP-A1 may overlap (or correspond to) the sensing area 1000SA shown in FIG. 1 or the sensing area 100SA shown in FIG. 2. According to some embodiments, the first area DP-A1 is shown in the shape of a circle, but may have various shapes, such as a polygon, an ellipse, a figure having at least one curved side, or an irregular shape, and is not limited to any one embodiment.

The display panel 100 may include a plurality of pixels PX. The display panel 100 may include a first pixel PX1 including a light emitting element located in the first area DP-A1, a second pixel PX2 including a light emitting element located in the second area DP-A2, and a third pixel PX3 including a light emitting element located in the third area DP-A3. Each of the first pixel PX1, the second pixel PX2, and the third pixel PX3 may include the pixel circuit PC shown in FIG. 4. The first pixel PX1, the second pixel PX2, and the third pixel PX3 shown in FIG. 5A are shown based on positions of corresponding light emitting elements LD (see FIG. 4). Meanwhile, pixels in which both the light emitting element and the pixel circuit are located in the second area DP-A2, or both the light emitting element and the pixel circuit are located in the third area DP-A3 may be referred to as display pixels.

Each of the first pixel PX1, the second pixel PX2, and the third pixel PX3 may be provided in plurality. In this case, each of the first to third pixels PX1, PX2, and PX3 may include a red pixel, a green pixel, and a blue pixel, and may further include a white pixel according to some embodiments.

The first area DP-A1, the second area DP-A2, and the third area DP-A3 may be classified according to light transmittance or resolution. Light transmittance and resolution are measured within a reference area. The first area DP-A1 may have higher light transmittance than the second and third areas DP-A2 and DP-A3. This is because the occupied area ratio of the light blocking structure described later is lower in the first area DP-A1 than in the second area DP-A2 and the third area DP-A3. The non-occupying area of the light blocking structure corresponds to the transmitting area of the light signal. The light blocking structure may include a conductive pattern of a circuit layer, a pixel defining film, a pixel defining pattern, and the like, which will be described later.

The third area DP-A3 may have higher resolution than the first area DP-A1 and the second area DP-A2. In the third area DP-A3, a greater number of light emitting elements may be located within the reference area (or the same area) compared to the first area DP-A1 and the second area DP-A2.

When classified based on light transmittance, the first area DP-A1 may be a first transmittance area, the second area DP-A2 and the third area DP-A3 may be different parts of the second transmittance area separated from the first transmittance area. Transmittance of the second area DP-A2 and the third area DP-A3 may be substantially the same. Even if the transmittance of the second area DP-A2 and the third area DP-A3 are not the same, because the transmittance of the first area DP-A1 is considerably higher than that of each of the second and third areas DP-A2 and DP-A3, when the first area DP-A1 is defined as a first transmittance area, the second area DP-A2 and the third area DP-A3 may be defined as a second transmittance area.

When classified based on resolution, the first area DP-A1 may be a first resolution area having a first resolution, and the second area DP-A2 and the third area DP-A3 may be second resolution areas having a second resolution. The first resolution of the first resolution area may be lower than the second resolution of the second resolution area. Resolution may be classified as the number of light emitting elements located per reference area. The number of light emitting elements per reference area of the first area DP-A1 may be less than the number of light emitting elements per reference area of the second area DP-A2. The number of light emitting elements per reference area of the second area DP-A2 may be substantially the same as the number of light emitting elements per reference area of the third area DP-A3.

Referring to FIG. 5B, the first pixel PX1 may include a first light emitting element LD1 and a first pixel circuit PC1 electrically connected to the first light emitting element LD1. The second pixel PX2 may include a second light emitting element LD2 and a second pixel circuit PC2 for driving the second light emitting element LD2, and the third pixel PX3 may include a third light emitting element LD3 and a third pixel circuit PC3 for driving the third light emitting element LD3.

The first light emitting element LD1 is located in the first area DP-A1, and the first pixel circuit PC1 is located in the second area DP-A2. The second light emitting element LD2 and the second pixel circuit PC2 are located in the second area DP-A2. The third light emitting element LD3 and the third pixel circuit PC3 are located in the third area DP-A3.

In order to increase the light transmittance of the first area DP-A1, the first pixel circuit PC1 is moved from the first area DP-A1 to the second area DP-A2. The light blocking structure such as a transistor is removed to increase the occupancy rate of the transmissive area, and as a result, the transmittance of the first area DP-A1 may be relatively improved. The first pixel circuit PC1 may be located in the peripheral area DP-NA other than the second area DP-A2.

Meanwhile, the first pixel PX1 may include first and second sub-pixels SPX1 to SPX2. The first pixel PX1 may further include a third sub-pixel SPX3. The first sub-pixel SPX1 includes a first sub-light emitting element SLD1 spaced apart from the first sub-pixel circuit SPC1 in the first direction DR1. The second sub-pixel PX2 includes a second sub-light emitting element SLD2 spaced apart from the second sub-pixel circuit SPC2 in the first direction DR1, and the third sub-pixel PX3 includes a third sub-light emitting element SLD3 spaced apart from the third sub-pixel circuit SPC3 in the second direction DR2.

According to some embodiments, the sub-light emitting element and sub-pixel circuit included in the sub-pixel located on the right side of the first area DP-A1 may have a similar arrangement relationship with the first sub-light emitting element SLD1 and the first sub-pixel circuit SPC1 located on the left side of the first area DP-A1. the sub-light emitting element and a sub-pixel circuit included in a sub-pixel located below the first area DP-A1 may have a similar arrangement relationship with the third sub-light emitting element SLD3 and the third sub-pixel circuit SPC3 located above the first area DP-A1. In FIG. 5C, the first electrodes AE1, AE2, and AE3 of the light emitting element are shown to represent the first light emitting element LD1, the second light emitting element LD2, and the third light emitting element LD3, respectively. In order to improve the transmittance of the first area DP-A1, the first light emitting element LD1 is located less than the third light emitting element LD3 within the reference area. For example, the resolution of the first area DP-A1 may be about ½, ⅜, ⅓, ¼, 2/9, ⅛, 1/9, or 1/16 of the resolution of the third area DP-A3. For example, the resolution of the third area DP-A3 may be about 400 ppi or more, and the resolution of the first area DP-A1 may be about 200 ppi or about 100 ppi. However, this is only an example and is not particularly limited thereto. Meanwhile, in order to increase the luminance of the first region DP-A1, the first electrode AE1 of the first light emitting element LD1 may have a larger area than the first electrode AE3 of the third light emitting element LD3.

At least a part of an area in the first area DP-A1 where the first light emitting element LD1 is not located may be defined as a transmissive area. For example, in the first area DP-A1, at least a part of an area in which the first electrode AE1 of the first light emitting element LD1 is not located may be defined as a transmissive area.

In order to secure an area in the second area DP-A2 where the first pixel circuit PC1 is located, within the reference area, the second light emitting element LD2 is located less than the third light emitting element LD3. In the second area DP-A2, the first pixel circuit PC1 is located in an area where the second pixel circuit PC2 is not located.

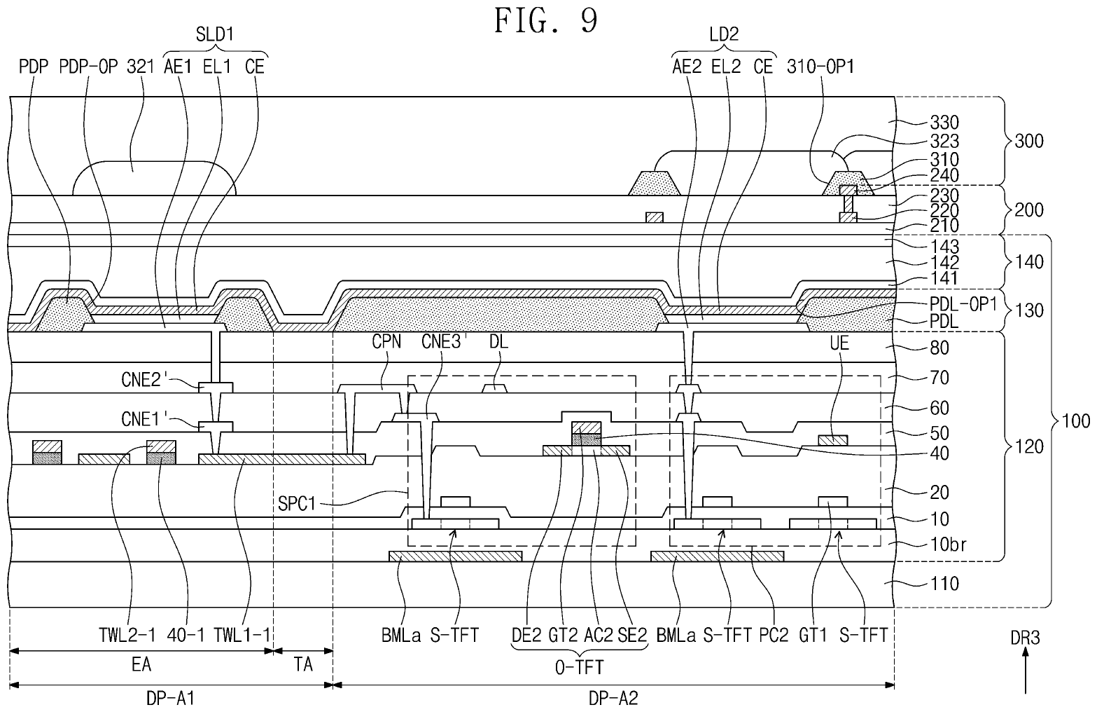

The first light emitting element LD1 may be electrically connected to the first pixel circuit PC1 through a connection wiring TWL. The connection wiring TWL overlaps the first area DP-A1 and the second area DP-A2. The connection wiring TWL may overlap with a transmissive area TA (see FIG. 8). At least a portion of the connection wiring TWL may include a transparent conductive material. In the first area DP-A1 of FIG. 5C, at least a part of the area where the first electrode AE1 is not located may be a substantially transmissive area TA. The transmissive area TA will be described in detail later in FIG. 8.

Meanwhile, the first to third sub-light emitting elements SLD1 to SLD3 located in the first area DP-A1 may be electrically connected to the first to third sub-pixel circuits SPC1 to SPC3, respectively. The different first light emitting elements SLD1 to SLD3 may be electrically connected to different first to third sub-pixel circuits SPC1 to SPC3, respectively, through the connection wiring TWL on different layers. By arranging the connection wiring TWL on different layers, compared to the case where the connection wiring TWL is arranged on the same layer, connection wiring may be efficiently arranged within the same area.

The first electrodes AE1, AE2, and AE3 may have curved edges. The first electrodes AE1, AE2, and AE3 having curved edges may minimize light diffraction. In particular, the first electrode AE1 of the first light emitting element LD1 may minimize diffraction of light passing through the transmissive area.

The first electrode AE1 of the first light emitting element LD1 may have an elliptical shape on a plane. The first electrode AE1 may secure an emission area and a connection area for the connection wiring TWL.

Referring to FIG. 5D, first light emitting elements LD1 of three colors are shown. The first electrode AE1-R, the first electrode AE1-G, and the first electrode AE1-B may represent a first light emitting element LD1 of a first color, a first light emitting element LD1 of a second color, and a first light emitting element LD1 of a third color, respectively. The first color may be red, the second color may be green, and the third color may be blue, but are not limited thereto, and the first to third colors may be other three main colors.

First to fourth light emitting element rows PXL1 to PXL4 located in the first area DP-A1 are illustrated. In each of the first and third light emitting element rows PXL1 and PXL3, first electrodes AE1-G of a second color may be arranged along the first direction DR1. In each of the second and fourth light emitting element rows PXL2 and PXL4, the first electrodes AE1-R of the first color and the first electrodes AE1-B of the third color may be alternately arranged along the first direction DR1. In the second direction DR2, the first electrodes AE1-R of the first color of the second light emitting element row PXL2 are aligned with the first electrode AE1-B of the third color of the fourth light emitting element row PXL4. The arrangement of the first to fourth light emitting element rows PXL1 to PXL4 may extend to the second area DP-A2 and the third area DP-A3.

The first electrodes AE1-R, AE1-G, and AE1-B located in the partial area 300A1 may correspond to first electrodes of the first pixel PX1 located on the left side of the first area DP-A1 shown in FIG. 5B, and the first electrodes AE1-R, AE1-G, and AE1-B located in the other partial area 300A2 may correspond to the first electrodes of the first pixel PX1 located above the first area DP-A1 shown in FIG. 5B. Extension directions of the connection wiring TWL may be different according to positions of the first electrodes AE1-R, AE1-G, and AE1-B.

Referring to FIG. 5E, the first pixel circuit PC1 may be located in a fourth area other than the first area DP-A1, the second area DP-A2, and the third area DP-A3. For example, as shown in FIG. 5E, the first pixel circuit PC1 may be located in the peripheral area DP-NA. When the first pixel circuit PC1 is located in the peripheral area DP-NA, the connection wiring TWL may overlap the first area DP-A1, the second area DP-A2, the third area DP-A3, and the peripheral area DP-NA.

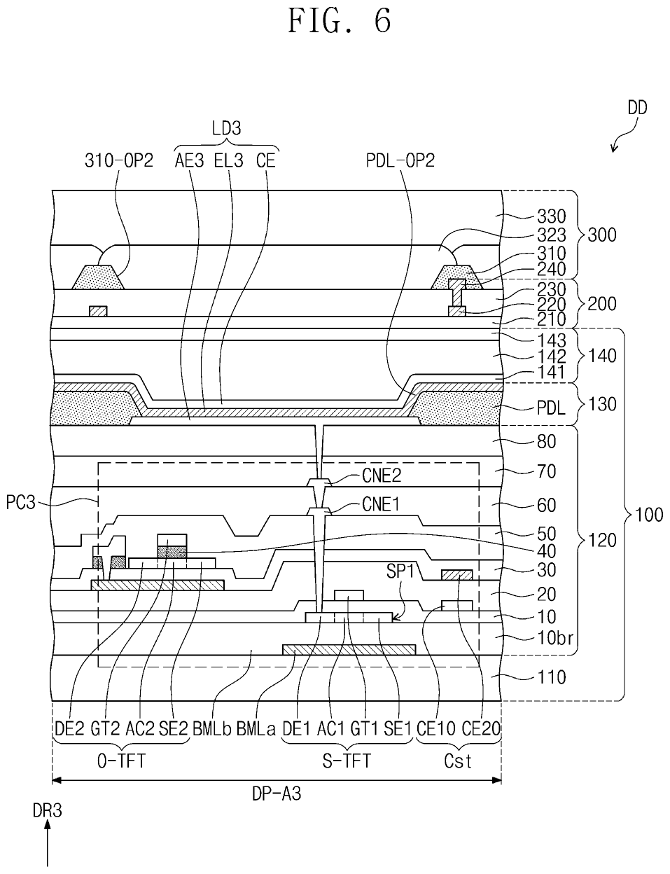

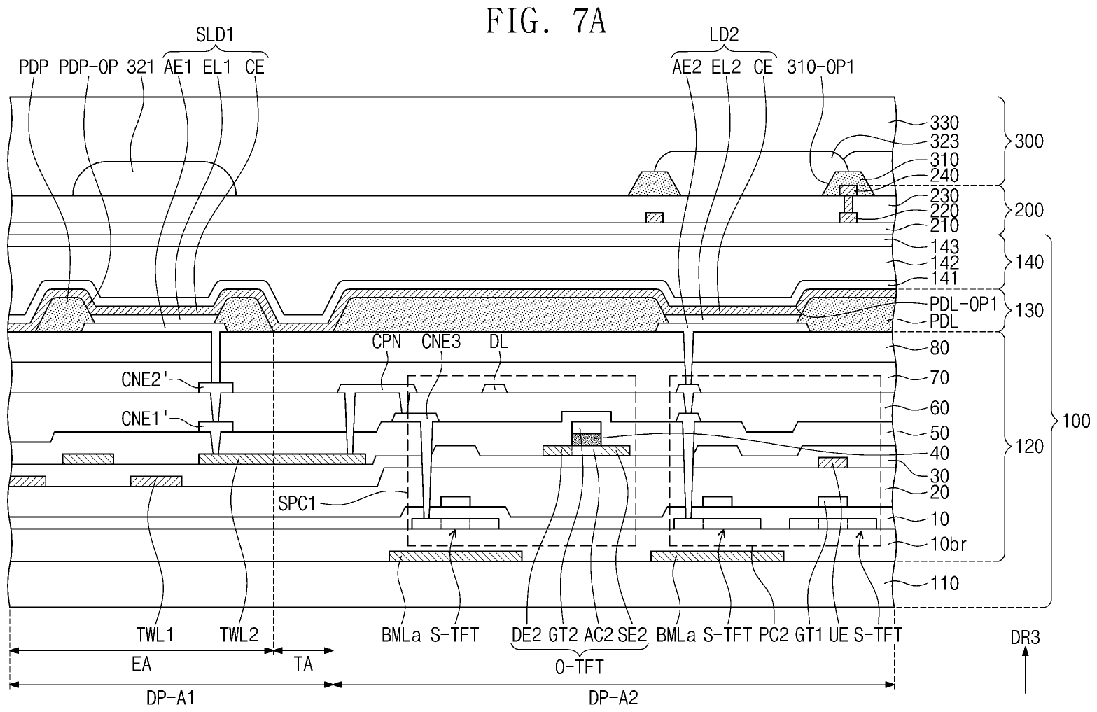

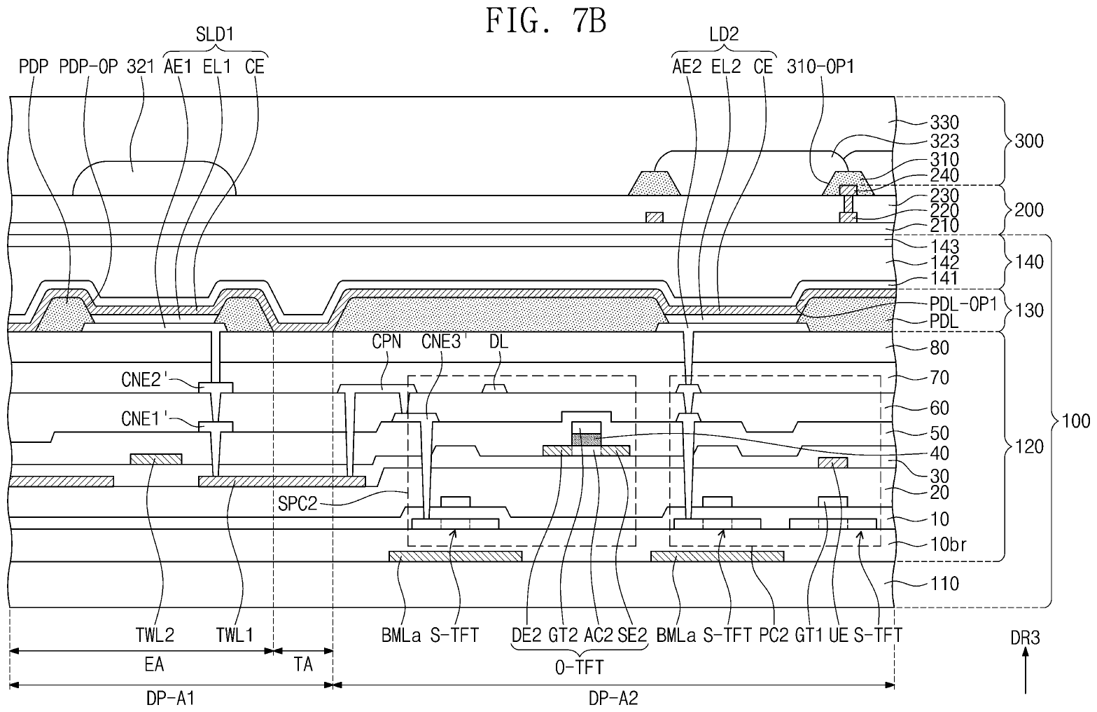

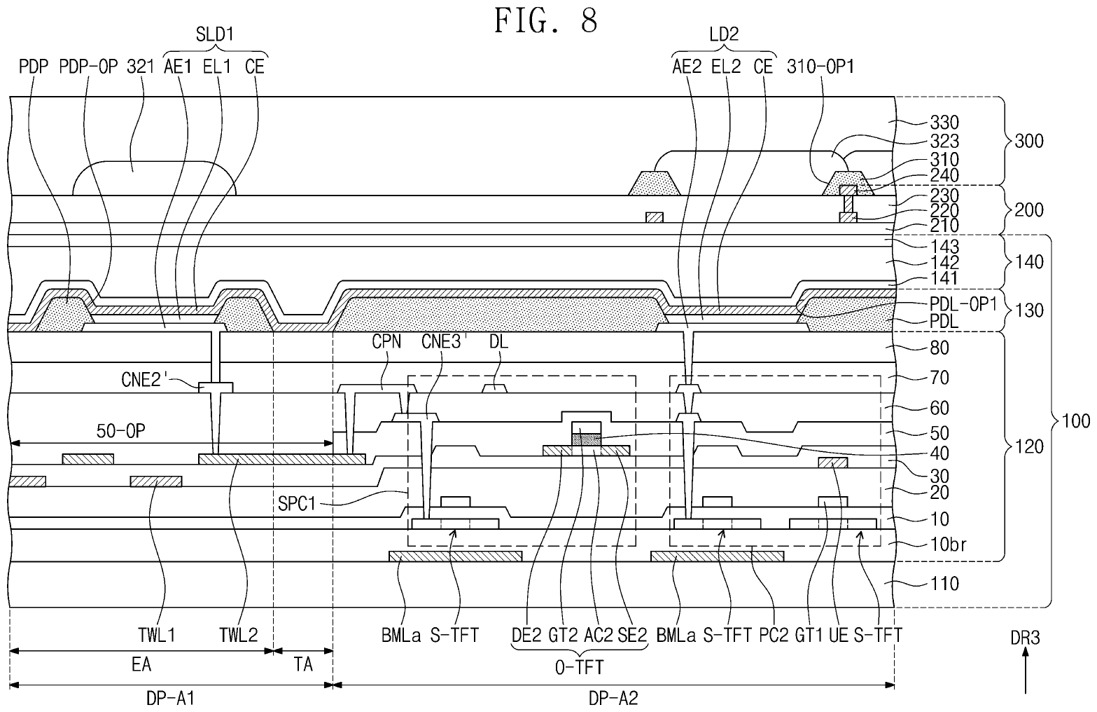

FIG. 6 is a cross-sectional view corresponding to the third area DP-A3 of the display device DD according to some embodiments. FIG. 7A is a cross-sectional view corresponding to the first area DP-A1 and the second area DP-A2 of the display device according to some embodiments. FIG. 7B is a cross-sectional view corresponding to the first area DP-A1 and the second area DP-A2 of the display device according to some embodiments. FIG. 7A shows that a first sub-light emitting element SLD1 is connected to a first transistor S-TFT through a second connection wiring TWL2 and FIG. 7B shows that the second sub-light emitting element LD2 shown in FIG. 7A is connected to the first transistor S-TFT through a first connection wiring TWL1. The first sub-light emitting element SLD1 shown in FIG. 7A and the second sub-light emitting element SLD2 shown in FIG. 7B may be different from each other. For example, the first sub-light emitting element SLD1 shown in FIG. 7A may be the first sub-light emitting element SLD1 shown in FIG. 5B, and the second sub-light emitting element SLD2 shown in FIG. 7B may be the second or third sub-light emitting element SLD2 or SLD3 (see FIG. 5B). Hereinafter, the common contents of FIGS. 6 to 7B will be described together, and only when explaining the relationship between the first light emitting elements SLD1 and SLD2 and the connection wirings TWL1 and TWL2, which is the difference between FIGS. 7A and 7B, FIGS. 7A and 7B are distinguished and described.

FIG. 6 shows the silicon transistor S-TFT and oxide transistor O-TFT of the third light emitting element LD3 and the third pixel circuit PC3 (see FIG. 5C). In the equivalent circuit shown in FIG. 4, the third and fourth transistors T3 and T4 may be oxide transistors O-TFT, and the remaining transistors may be silicon transistors S-TFT. FIGS. 7A and 7B show parts of the first light emitting elements SLD1 and SLD2 and the first pixel circuits SPC1 and SPC2, and a part of the second light emitting element LD2 and the second pixel circuit PC2. Specifically, FIG. 7A shows the first sub-light emitting element SLD1 and the first sub-pixel circuit SPC1, and FIG. 7B shows the second sub-light emitting element SLD2 and the second sub-pixel circuit SPC2. In FIGS. 7A and 7B, the silicon transistor S-TFT connected to the light emitting elements SPD1, SPD2, and LD2 is the sixth transistor T6 shown in FIG. 4, and the silicon transistor S-TFT not connected to the light emitting elements SPD1, SPD2, and LD2 may be any one of the first, second, fifth, and seventh transistors T1, T2, T5, and T7 shown in FIG. 4. Meanwhile, the silicon transistor S-TFT may be referred to as a first silicon transistor when connected to the first sub-light emitting element SLD1, and referred to as a second silicon transistor when connected to the second sub-light emitting element SLD2. In addition, the oxide transistor O-TFT may be referred to as a first oxide transistor when connected to the first sub-light emitting element SLD1, and may be referred to as a second oxide transistor when connected to the second sub-light emitting element SLD2. The buffer layer 10br may be located on the base layer 110. The buffer layer 10br may prevent diffusion of metal atoms or impurities from the base layer 110 into the upper silicon semiconductor pattern SP1. The silicon semiconductor pattern SP1 includes the active region AC1 of the silicon transistor S-TFT. The buffer layer 10br may control a heat supply rate during a crystallization process for forming the silicon semiconductor pattern SP1 so that the silicon semiconductor pattern SP1 is uniformly formed.

A first back metal layer BMLa may be located below the silicon transistor S-TFT, and a second back metal layer BMLb may be located below the oxide transistor O-TFT. The first and second back metal layers BMLa and BMLb may be arranged to overlap the first to third pixel circuits SPC1, SPC2, PC2, and PC3. The first and second back metal layers BMLa and BMLb may block external light from reaching the first to third pixel circuits SPC1, SPC2, PC2, and PC3.

The first back metal layer BMLa may be arranged to correspond to at least a partial area of each of the first to third pixel circuits SPC1, SPC2, PC2, and PC3. The first back metal layer BMLa may be arranged to overlap the driving transistor T1 (see FIG. 4) implemented with the silicon transistor S-TFT.

The first back metal layer BMLa may be located between the base layer 110 and the buffer layer 10br. According to some embodiments, an inorganic barrier layer may be further located between the first back metal layer BMLa and the buffer layer 10br. The first back metal layer BMLa may be connected to electrodes or wires, and may receive a constant voltage or signal from them. According to some embodiments, the first back metal layer BMLa may be a floating electrode in a form isolated from other electrodes or wires.

The second back metal layer BMLb may be arranged to correspond to a lower portion of the oxide transistor O-TFT. A second back metal layer BMLb may be located between the second insulating layer 20 and the third insulating layer 30. The second back metal layer BMLb may be located on the same layer as the second electrode CE20 of the storage capacitor Cst. The second back metal layer BMLb may be connected to the contact electrode BML2-C to receive a constant voltage or signal. The contact electrode BML2-C may be located on the same layer as the second gate electrode GT2 of the oxide transistor O-TFT.

Each of the first back metal layer BMLa and the second back metal layer BMLb may include a reflective metal. For example, each of the first back metal layer BMLa and the second back metal layer BMLb may include silver (Ag), alloy containing silver (Ag), molybdenum (Mo), alloy containing molybdenum, aluminum (Al), alloy containing aluminum, aluminum nitride (AlN), tungsten (W), tungsten nitride (WN), copper (Cu), and p+ doped amorphous silicon. The first back metal layer BMLa and the second back metal layer BMLb may include the same material or different materials.

According to some embodiments, the second back metal layer BMLb may be omitted. The first back metal layer BMLa may extend to a lower portion of the oxide transistor O-TFT so that the first back metal layer BMLa may block light incident on the lower portion of the oxide transistor O-TFT.

The silicon semiconductor pattern SP1 may be located on the buffer layer 10br. The silicon semiconductor pattern SP1 may include a silicon semiconductor. For example, the silicon semiconductor may include amorphous silicon, polycrystalline silicon, or the like. For example, the silicon semiconductor pattern SP1 may include low-temperature polysilicon.

FIG. 6 only shows a portion of the silicon semiconductor pattern SP1 located on the buffer layer 10br, and the silicon semiconductor pattern SP1 may be further located in other areas. The silicon semiconductor pattern SP1 may be arranged in a specific rule across pixels. The silicon semiconductor pattern SP1 may have different electrical properties depending on whether it is doped or not. The silicon semiconductor pattern SP1 may include a first area having high conductivity and a second area having low conductivity. The first area may be doped with an N-type dopant or a P-type dopant. The P-type transistor may include a doping area doped with a P-type dopant, and the N-type transistor may include a doping area doped with an N-type dopant. The second area may be a non-doped area or an area doped with a lower concentration than the first area.

The conductivity of the first area may be greater than that of the second area, and the first area may substantially serve as an electrode or a signal line. The second area may substantially correspond to an active area (or channel) of the transistor. In other words, a part of the silicon semiconductor pattern SP1 may be an active area of the transistor, another part may be a source or drain of the transistor, and another part may be a connection electrode or a connection signal line.

A source area SE1 (or source), an active area AC1 (or channel), and a drain area DE1 (or drain) of the silicon transistor S-TFT may be formed from the silicon semiconductor pattern SP1. The source area SE1 and the drain area DE1 may extend in opposite directions from the active area AC1 on a cross-section.

The first insulating layer 10 may be located on the buffer layer 10br. The first insulating layer 10 overlaps a plurality of pixels in common and may cover the silicon semiconductor pattern SP1. The first insulating layer 10 may be an inorganic layer and/or an organic layer, and may have a single layer or multilayer structure. The first insulating layer 10 may include at least one of aluminum oxide, titanium oxide, silicon oxide, silicon nitride, silicon oxynitride, zirconium oxide, or hafnium oxide. According to some embodiments, the first insulating layer 10 may be a single-layer silicon oxide layer. In addition to the first insulating layer 10, the insulating layer of the circuit layer 120 to be described later may be an inorganic layer and/or an organic layer, and may have a single layer or multilayer structure. The inorganic layer may include at least one of the above-mentioned materials, but embodiments according to the present disclosure are not limited thereto.

The first gate electrode GT1 of the silicon transistor S-TFT may be located on the first insulating layer 10. The first gate electrode GT1 may be a part of the metal pattern. The first gate electrode GT1 may overlap the active area AC1. In a process of doping the silicon semiconductor pattern SP1, the first gate electrode GT1 may function as a mask. The first gate electrode GT1 may include titanium (Ti), silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), indium tin oxide (ITO), indium zinc oxide (IZO), and the like, but is not particularly limited thereto.

The second insulating layer 20 is located on the first insulating layer 10 and may cover the first gate electrode GT1. The third insulating layer 30 may be located on the second insulating layer 20. A second electrode CE20 of the storage capacitor Cst may be located between the second insulating layer 20 and the third insulating layer 30. Also, the first electrode CE10 of the storage capacitor Cst may be located between the first insulating layer 10 and the second insulating layer 20. Meanwhile, the first gate electrode GT1 included in the first sub-pixel circuit SPC1 may be referred to as a first gate electrode and the first gate electrode GT1 included in the second sub-pixel circuit SPC1 may be referred to as a third gate electrode.

The upper electrode UE may be located on the second insulating layer 20. The upper electrode UE may constitute the storage capacitor Cst together with the first gate electrode GT1. The upper electrode UE may include transparent conductive oxide (TCO) such as indium tin oxide (ITO), indium zinc oxide (IZO), indium gallium zinc oxide (IGZO), zinc oxide (ZnO) or indium oxide (In₂O₃). Meanwhile, the upper electrode UE may be referred to as a first upper electrode or a second upper electrode. For example, an upper electrode included in the first sub-pixel circuit SPC1 (see FIG. 5B) may be referred to as a first upper electrode, and an upper electrode included in the second sub-pixel circuit SPC2 (see FIG. 5B) may be referred to as a second upper electrode.

The oxide semiconductor pattern SP2 may be located on the third insulating layer 30. The oxide semiconductor pattern SP2 may include an active area AC2 of an oxide transistor O-TFT, which will be described later. The oxide semiconductor pattern SP2 may include an oxide semiconductor. The oxide semiconductor pattern SP2 may include transparent conductive oxide (TCO) such as indium tin oxide (ITO), indium zinc oxide (IZO), indium gallium zinc oxide (IGZO), zinc oxide (ZnO) or indium oxide (In₂O₃).

The oxide semiconductor may include a plurality of areas divided according to whether the transparent conductive oxide is reduced. An area where the transparent conductive oxide is reduced (hereinafter referred to as a reduced area) has higher conductivity than an area where the transparent conductive oxide is not reduced (hereinafter referred to as a non-reduced area). The reduced area actually serves as the source/drain or signal line of the transistor. The non-reducing area substantially corresponds to the semiconductor area (or active area or channel) of the transistor. In other words, a portion of the oxide semiconductor pattern SP2 may be a semiconductor area of a transistor, another portion may be a source/drain area of a transistor, and another portion may be a signal transmission area.

A source area SE2 (or source), an active area AC2 (or channel), and a drain area DE2 (or drain) of the oxide transistor O-TFT may be formed from the oxide semiconductor pattern SP2. The source area SE2 and the drain area DE2 may extend in opposite directions from the active area AC2 on a cross section.

The fourth insulating layer 40 may be located on the third insulating layer 30. As shown in FIG. 6, the fourth insulating layer 40 may be an insulating pattern overlapping the second gate electrode GT2 of the oxide transistor O-TFT and exposing the source area SE2 and the drain area DE2 of the oxide transistor O-TFT. According to some embodiments, the fourth insulating layer 40 may overlap a plurality of pixels in common and cover the oxide semiconductor pattern SP2.

As shown in FIG. 6, the second gate electrode GT2 of the oxide transistor O-TFT is located on the fourth insulating layer 40. The second gate electrode GT2 of the oxide transistor O-TFT may be a part of the metal pattern. The second gate electrode GT2 of the oxide transistor O-TFT overlaps the active area AC2 of the oxide transistor O-TFT.

The fifth insulating layer 50 is located on the fourth insulating layer 40 and may cover the second gate electrode GT2. The first connection electrode CNE1 may be located on the fifth insulating layer 50. The first connection electrode CNE1 may be connected to the drain area DE1 of the silicon transistor S-TFT through a contact hole passing through the first to fifth insulating layers 10, 20, 30, 40, and 50.

The sixth insulating layer 60 may be located on the fifth insulating layer 50. The second connection electrode CNE2 may be located on the sixth insulating layer 60. The second connection electrode CNE2 may be connected to the first connection electrode CNE1 through a contact hole penetrating the sixth insulating layer 60. The seventh insulating layer 70 is located on the sixth insulating layer 60 and may cover the second connection electrode CNE2. The eighth insulating layer 80 may be located on the seventh insulating layer 70.

Each of the sixth insulating layer 60, the seventh insulating layer 70, and the eighth insulating layer 80 may be an organic layer. For example, each of the sixth insulating layer 60, the seventh insulating layer 70, and the eighth insulating layer 80 may include Benzocyclobutene (BCB), polyimide, Hexamethyldisiloxane (HMDSO), Polymethylmethacrylate (PMMA), or general purpose polymers such as polystyrene (PS), polymer derivatives having phenolic groups, acrylic polymers, imide-based polymers, arylether-based polymers, amide-based polymers, fluorine-based polymers, p-xylene-based polymers, vinyl alcohol-based polymers, blends thereof, and the like.

Meanwhile, in FIGS. 7A, 7B, and 8, the first and second insulating layers 10 and 20 are referred to as lower insulating layers 10 and 20, and the third insulating layer 30 is referred to as an upper insulating layer 30. Also, the fifth insulating layer 50 is referred to as a cover insulating layer 50.

That is, the insulating layer may include the lower insulating layers 10 and 20 and the upper insulating layer 30. The lower insulating layers 10 and 20 may be located below the upper electrode UE. The upper insulating layer 30 may be located on the upper electrode UE. A cover insulating layer 50 may be located on the upper insulating layer 30. An oxide semiconductor pattern SP2, a fourth insulating layer 40 serving as an insulating pattern, and a second gate electrode GT2 may be located between the upper insulating layer 30 and the cover insulating layer 50. Meanwhile, the second gate electrode GT2 included in the first sub-pixel circuit SPC1 may be referred to as a second gate electrode, and the second gate electrode GT2 included in the second sub-pixel circuit SPC2 may be referred to as a fourth gate electrode.

The third light emitting element LD3 may include a first electrode AE3 (or pixel electrode), an emission layer EL3, and a second electrode CE (or common electrode). The second electrodes CE of the first light emitting elements SLD1 and SLD2 and the second light emitting element LD2, which will be described later, may have an integral shape with the second electrode CE of the third light emitting element LD3. That is, the second electrode CE may be provided in common to the first light emitting elements SLD1 and SLD2, the second light emitting element LD2, and the third light emitting element LD3.

The first electrode AE3 of the third light emitting element LD3 may be located on the eighth insulating layer 80. The first electrode AE3 of the third light emitting element LD3 may be a (semi) transmissive electrode or a reflective electrode. According to some embodiments, each of the first electrodes AE3 of the third light emitting element LD3 may include a reflective layer formed of Ag, Mg, Al, Pt, Pd, Au, Ni, Nd, Ir, Cr, or a compound thereof, and a transparent or semi-transparent electrode layer formed on the reflective layer. The transparent or semi-transparent electrode layer may include at least one or more selected from the group consisting of indium tin oxide (ITO), indium zinc oxide (IZO), indium gallium zinc oxide (IGZO), zinc oxide (ZnO) or indium oxide (In₂O₃), and aluminum doped zinc oxide (AZO). For example, the first electrode AE3 of the third light emitting element LD3 may include a stacked structure of ITO/Ag/ITO.

The pixel defining film PDL may be located on the eighth insulating layer 80. The pixel defining film PDL includes the same materials and may be formed through the same process. The pixel defining film PDL may have a property of absorbing light, and for example, the pixel defining film PDL may have a black color. The pixel defining film PDL may include a black coloring agent. The black coloring agent may include a black dye and a black pigment. The black coloring agent may include a metal such as carbon black or chromium, or an oxide thereof. The pixel defining film PDL may correspond to a light blocking pattern having light blocking characteristics.

The pixel defining film PDL may cover a portion of the first electrode AE3 of the third light emitting element LD3. For example, a second opening PDL-OP2 exposing a portion of the first electrode AE3 of the third light emitting element LD3 may be defined in the pixel defining film PDL. The pixel defining film PDL may increase a distance between the edge of the first electrode AE3 of the third light emitting element LD3 and the second electrode CE. Accordingly, it may prevent an arc or the like from occurring at the edges of the first electrodes AE3 by the pixel defining film PDL.

According to some embodiments, a hole control layer may be located between the first electrode AE3 and the light emitting layer EL3. The hole control layer may include a hole transport layer and may further include a hole injection layer. An electronic control layer may be located between the light emitting layers EL3 and the second electrode CE. The electron control layer may include an electron transport layer and may further include an electron injection layer. The hole control layer and the electron control layer may be commonly formed in a plurality of pixels PX (see FIG. 5A) using an open mask.

The encapsulation layer 140 may be located on the light emitting element layer 130. The encapsulation layer 140 may include an inorganic layer 141, an organic layer 142, and an inorganic layer 143 that are sequentially stacked, but the layers constituting the encapsulation layer 140 are not limited thereto.

The inorganic layers 141 and 143 may protect the light emitting element layer 130 from moisture and oxygen, and the organic layer 142 may protect the light emitting element layer 130 from foreign substances such as dust particles. The inorganic layers 141 and 143 may include a silicon nitride layer, a silicon oxynitride layer, a silicon oxide layer, a titanium oxide layer, or an aluminum oxide layer. The organic layer 142 may include an acrylic organic layer, but is not limited thereto.

The sensor layer 200 may be located on the display panel 100. The sensor layer 200 may be referred to as a sensor, an input sensing layer, or an input sensing panel. The sensor layer 200 may include a base layer 210, a first conductive layer 220, a detection insulating layer 230, and a second conductive layer 240.

The base layer 210 may be directly located on the display panel 100. The base layer 210 may be an inorganic layer including at least one of silicon nitride, silicon oxynitride, or silicon oxide. Alternatively, the base layer 210 may be an organic layer including an epoxy resin, an acrylic resin, or an imide resin. The base layer 210 may have a single layer structure or may have a multilayer structure stacked along the third direction DR3.

Each of the first conductive layer 220 and the second conductive layer 240 may have a single layer structure or may have a multilayer structure stacked along the third direction DR3. The first conductive layer 220 and the second conductive layer 240 may include conductive lines defining mesh-shaped detection electrodes. The conductive lines do not overlap the first opening PDL-OP1, the second opening PDL-OP2, and the openings PDP-OP1 and PDP-OP2, and overlap the pixel defining pattern PDP and the pixel defining film PDL. The detection electrode defined by the first conductive layer 220 and the second conductive layer 240 overlaps at least the third area DP-A3 shown in FIG. 5A.

The single-layered conductive layer may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), indium zinc tin oxide (IZTO), and the like. In addition, the transparent conductive material may include a conductive polymer such as PEDOT, metal nanowires, graphene, and the like.

The multilayered conductive layer may include metal layers. The metal layers may have a three-layer structure of, for example, titanium/aluminum/titanium. The multilayered conductive layer may include at least one metal layer and at least one transparent conductive layer.

The detection insulating layer 230 may be located between the first conductive layer 220 and the second conductive layer 240. The detection insulating layer 230 may include an inorganic film. The inorganic film may include at least one of aluminum oxide, titanium oxide, silicon oxide, silicon nitride, silicon oxynitride, zirconium oxide, or hafnium oxide.

Alternatively, the detection insulating layer 230 may include an organic film. The organic film may include at least one of acrylic resin, methacrylic resin, polyisoprene, vinyl resin, epoxy resin, urethane resin, cellulose resin, siloxane resin, polyimide resin, polyamide resin, or perylene resin.

The anti-reflection layer 300 may be located on the sensor layer 200. The anti-reflection layer 300 may include a partition layer 310, a first color filter 321, a second color filter 322, a third color filter 323, and a planarization layer 330.

The material constituting the partition layer 310 is not particularly limited as long as it is a material that absorbs light. The partition layer 310 is a layer having a black color, and according to some embodiments, the partition layer 310 may include a black coloring agent. The black coloring agent may include a black dye and a black pigment. The black coloring agent may include a metal such as carbon black or chromium, or an oxide thereof.

The partition layer 310 may cover the second conductive layer 240 of the sensor layer 200. The partition layer 310 may prevent reflection of external light by the second conductive layer 240. The partition layer 310 may overlap the second area DP-A2 (see FIG. 7A) and the third area DP-A3, and may not overlap the first area DP-A1 (see FIG. 7A). That is, as the partition layer 310 is not located in the first area DP-A1 (see FIG. 7A), the transmittance of the first area DP-A1 may be further relatively improved.

A second opening 310-OP2 may be defined in the partition layer 310. The second opening 310-OP2 may overlap the first electrode AE3 of the third light emitting element LD3. The third color filter 323 may overlap the third area DP-A3. The third color filter 323 may overlap the first electrode AE3 of the third light emitting element LD3. The third color filter 323 may cover the second opening 310-OP2. The third color filter 323 may contact the partition layer 310.

The planarization layer 330 may cover the partition layer 310 and the third color filter 323. The planarization layer 330 may include an organic material, and may provide a flat surface on the upper surface of the planarization layer 330. According to some embodiments, the planarization layer 330 may be omitted.

FIGS. 7A and 7B show a second area DP-A2 to which the fourth insulating layer 40 of the insulating pattern shown in FIG. 6 is applied. In FIGS. 7A and 7B, unlike the first pixel circuit PC1, the oxide transistor O-TFT of the second pixel circuit PC2 is not shown. Descriptions of the first pixel PX1 and the second pixel PX2 that are common to the third pixel PX3 described with reference to FIG. 6 will be omitted.

Referring to FIG. 7A, the first electrode AE1 of the first sub-light emitting element SLD1 may be electrically connected to the first sub-pixel circuit SPC1 located in the second area DP-A2. The first electrode AE1 of the first sub-light emitting element SLD1 may be electrically connected to the first silicon transistor S-TFT or the first oxide transistor O-TFT. FIG. 7A shows the first electrode AE1 of the first sub-light emitting element SLD1 connected to the first silicon transistor S-TFT.

Specifically, the first electrode AE1 of the first light emitting element SLD1 may be electrically connected to the first sub-pixel circuit SPC1 through the second connection wiring TWL2 and the connection electrodes CNE1′, CNE2′, CNE3′, and CPN. According to some embodiments, one of the connection electrodes CNE1′ and CNE2′ may be omitted. The second connection electrode CNE2′ may be omitted, and the first connection electrode CNE1′ may be directly connected to the second connection wiring TWL2. The first connection electrode CNE1′ and the second connection electrode CNE2′ may be omitted, and the first electrode AE1 may be directly connected to the second connection wiring TWL2.

Referring to FIG. 7B, the first electrode AE1 of the second sub-light emitting element SLD1 may be electrically connected to the second sub-pixel circuit SPC2 located in the second area DP-A2. The first electrode AE1 of the second sub-light emitting element LD2 may be electrically connected to the second silicon transistor S-TFT or the second oxide transistor O-TFT. FIG. 7B shows the first electrode AE1 of the second sub-light emitting element LD2 connected to the second silicon transistor S-TFT.

Specifically, the first electrode AE1 of the second sub-light emitting element SLD2 may be electrically connected to the second sub-pixel circuit SPC2 through the first connection wiring TWL1 and the connection electrodes CNE1′, CNE2′, and CPN. According to some embodiments, one of the connection electrodes CNE1′ and CNE2′ may be omitted. The second connection electrode CNE2′ may be omitted, and the first connection electrode CNE1′ may be directly connected to the first connection wiring TWL1. The first connection electrode CNE1′ and the second connection electrode CNE2′ may be omitted, and the first electrode AE1 may be directly connected to the first connection wiring TWL1.

The connection wirings TWL1 and TWL2 may overlap the transmissive area TA. The connection wirings TWL1 and TWL2 may include a light-transmitting material. The connection wirings TWL1 and TWL2, for example, may include transparent conductive oxide (TCO) such as indium tin oxide (ITO), indium zinc oxide (IZO), indium gallium zinc oxide (IGZO), zinc oxide (ZnO) or indium oxide (In₂O₃). Even if the connection wirings TWL1 and TWL2 overlap the transmissive area TA where the light signal moves, the transparent connection wirings TWL1 and TWL2 may minimize the deformation of the light signal such as diffraction.

The first connection wirings TWL1 may be spaced apart from each other. The second connection wirings TWL2 may be spaced apart from each other. The first connection wiring TWL1 and the second connection wiring TWL2 may be alternately arranged in one direction perpendicular to the third direction DR3.

The first connection wiring TWL1 and the second connection wiring TWL2 may be located on different layers. When arranging connection wirings on a single layer, the connection wirings must be spaced apart from each other, and there are restrictions on the number and arrangement of connection wirings that may be arranged per unit area. According to some embodiments, by including the first connection wiring TWL1 and the second connection wiring TWL2 located on different layers, the connection wirings may be more efficiently arranged than in the case of including connection wirings located on a single layer.

According to some embodiments, the first connection wiring TWL1 may overlap the first area DP-A1 and be located on the second insulating layer 20. That is, the first connection wiring TWL1 may be located on the lower insulating layers 10 and 20. The first connection wiring TWL1 may be covered by the third insulating layer 30. That is, the first connection wiring TWL1 may be covered by the upper insulating layer 30. Meanwhile, the upper insulating layer 30 may cover the upper electrode UE located on the same layer as the first connection wiring TWL1.

According to some embodiments, the second connection wiring TWL2 overlaps the first area DP-A1 and the second area DP-A2 and may be located on the third insulating layer 30. That is, the second connection wiring TWL2 may be located on the upper insulating layer 30. The second connection wiring TWL2 may be covered by the fifth insulating layer 50. That is, the second connection wiring TWL2 may be covered by the cover insulating layer 50.

The first connection wiring TWL1 may be located on the same layer as the upper electrode UE. The first connection wiring TWL1 may be located on the same insulating layer as the upper electrode UE. The first connection wiring TWL1 may be formed of the same material in the same process as the upper electrode UE. That is, in order to form the first connection wiring TWL1, a separate process other than the upper electrode UE forming process is not required. Accordingly, the stacked structure of the display device DD (see FIG. 2) may be simplified. In addition, in manufacturing the display device DD (see FIG. 2), the process may be simplified by reducing the number of masks required for the process.

The second connection wiring TWL2 may be located on the same layer as the oxide semiconductor pattern SP2. The second connection wiring TWL2 may be located on the same insulating layer as the oxide semiconductor pattern SP2. The second connection wiring TWL2 may be formed of the same material in the same process as the oxide semiconductor pattern SP2. That is, to form the second connection wiring TWL2, a separate process other than the oxide semiconductor pattern SP2 forming process is not required. Accordingly, the stacked structure of the display device DD (see FIG. 2) may be simplified. In addition, in manufacturing the display device DD (see FIG. 2), the process may be simplified by reducing the number of masks required for the process.

Meanwhile, the second connection wiring TWL2 may be formed from the same original oxide semiconductor layer as the oxide semiconductor pattern SP2. The original oxide semiconductor layer is divided into a plurality of patterns through an etching process, and the plurality of patterns include the oxide semiconductor pattern SP2 and the second connection wiring TWL2.

However, the oxide semiconductor pattern SP2 and the second connection wiring TWL2 have different electrical properties because subsequent processes are not completely identical. The second connection wiring TWL2 may have conductivity corresponding to the source area SE2 and the drain area DE2 of the oxide semiconductor pattern SP2. Hereinafter, the second connection wiring TWL2 and the source area SE2 of the oxide semiconductor pattern SP2 will be mainly described.

The second connection wiring TWL2 and the source area SE2 of the oxide semiconductor pattern SP2 may have higher conductivity than the active area AC2 of the oxide semiconductor pattern SP2. The second connection wiring TWL2 and the source area SE2 and drain area DE2 of the oxide semiconductor pattern SP2 may have a higher content of fluorine than the active area AC2 of the oxide semiconductor pattern SP2. In the process of forming the fourth insulating layer 40 of the insulating pattern, a fluorinated gas such as CF4 and/or SF6 is used as an etching gas because fluorine replaces oxygen in transparent conductive oxide TCO. A dry etching process using fluorine gas has similar results to doping a transparent conductive oxide (TCO) with fluorine.

The conductivity of the reduced TCO is increased. The active area AC2 of the oxide semiconductor pattern SP2 has a relatively low fluorine element content because the second gate electrode GT2 masks the fluorine gas.

The pixel defining pattern PDP may be located on the eighth insulating layer 80 to overlap the first area DP-A1. The pixel defining pattern PDP includes the same material as the pixel defining film PDL and may be formed through the same process. The pixel defining pattern PDP and the pixel defining film PDL may include a material through which light is transmitted. The pixel defining pattern PDP may cover a portion of the first electrode AE1 of the first light emitting element LD1. For example, the pixel defining pattern PDP may cover the edge of the first electrode AE1 of the first light emitting elements SLD1 and SLD2 and suppress the generation of an arc like the pixel defining film PDL.

In the first area DP-A1, an area overlapping the first electrode AE1 of the first light emitting element SLD1 and SLD2 and an area overlapping the pixel defining pattern PDP are defined as an element area EA, and the remaining area may be defined as a transmissive area TA. However, this is only an example, and the embodiments according to the present disclosure are not limited thereto. For example, when the pixel defining pattern PDP includes a transparent material, in the first area DP-A1, an area overlapping the first electrode AE1 of the first light emitting elements SLD1 and SLD2 may be defined as an element area, and the remaining area may be defined as a transmissive area.

A first opening 310-OP1 may be defined in the partition layer 310. The first opening 310-OP1 may overlap the first electrode AE2 of the second light emitting element LD2. The first color filter 321 may overlap the first area DP-A1, and the second color filter 322 may overlap the second area DP-A2. Each of the first color filter 321 and the second color filter 322 may overlap a corresponding one of the first electrodes AE1 and AE2.

Because the partition layer 310 does not overlap the first area DP-A1, the first color filter 321 may be spaced apart from the partition layer 310. That is, the first color filter 321 may not contact the partition layer 310. The second color filter 322 may cover the first opening 310-OP1. The planarization layer 330 may cover the partition layer 310, the first color filter 321, and the second color filter 322.

FIG. 8 is a cross-sectional view corresponding to a first area DP-A1 and a second area DP-A2 of a display device according to some embodiments.

Referring to FIG. 8, a portion of the second connection wiring TWL2 may be exposed from the fifth insulating layer 50 through the opening 50-OP. The opening 50-OP may be defined in a portion of the fifth insulating layer 50 corresponding to the first area DP-A1. A fluorinated gas such as CF4 and/or SF6 is used as an etching gas for forming the opening 50-OP, and in the process, conductivity of the second connection wiring TWL2 may be increased. A portion of the second connection wiring TWL2 exposed by the opening 50-OP may be covered by the sixth insulating layer 60 filling the opening 50-OP.

FIG. 9 is a cross-sectional view corresponding to a first area DP-A1 and a second area DP-A2 of a display device according to some embodiments.

Differences between the display device according to embodiments shown in FIG. 9 and the display device shown in FIG. 7A will be mainly described. FIG. 9 is different from the display device shown in FIG. 7A in that it does not include the third insulating layer 30.

Referring to FIG. 9, the upper electrode UE may be located on the second insulating layer 20. In FIG. 9, the second insulating layer 20 is defined as a lower insulating layer, the fifth insulating layer 50 is defined as an upper insulating layer, and the sixth to eighth insulating layers 60 to 80 are defined as uppermost insulating layers.

According to some embodiments, the upper electrode UE may be located on the same layer as the oxide semiconductor pattern SP2. Also, the first connection wiring TWL1-1 may be located on the same layer as the upper electrode UE and the oxide semiconductor pattern SP2. The first connection wiring TWL1-1, the upper electrode UE, and the oxide semiconductor pattern SP2 may be located on the lower insulating layer 20. The first connection wiring TWL1-1, the upper electrode UE, and the oxide semiconductor pattern SP2 may be covered by the upper insulating layer 50.

The first connection wiring TWL1-1 may be formed of the same material as the upper electrode UE and the oxide semiconductor pattern SP2 in the same process. That is, in order to form the first connection wiring TWL1-1, a separate process other than the forming of the upper electrode UE and the forming of the oxide semiconductor pattern SP2 is not required. Accordingly, the stacked structure of the display device DD (see FIG. 2) may be simplified and in manufacturing the display device DD (see FIG. 2), the process may be simplified by reducing the number of masks required for the process.

Meanwhile, the first connection wiring TWL1-1 has different electrical properties because the oxide semiconductor pattern SP2 and subsequent processes are not completely identical. The first connection wiring TWL1-1 may have electrical conductivity corresponding to the source area SE2 and drain area DE2 of the oxide semiconductor pattern SP2. The same details as those described for the second connection wiring TWL2 (see FIG. 7A) and the oxide semiconductor pattern SP2 in FIG. 7A may be applied.

According to some embodiments, the second connection wiring TWL2-1 may be located on a layer different from that of the first connection wiring TWL1-1. In the case of arranging connection wirings on a single layer, the connection wirings must be spaced apart from each other, and there is a limit to the arrangement form of connection wirings that may be arranged per unit area. According to some embodiments, by including the first connection wiring TWL1-1 and the second connection wiring TWL2-1 located on different layers, connection wiring may be arranged more efficiently compared to the case of including connection wirings arranged on a single layer.

The second connection wiring TWL2-1 may be located on the same layer as the second gate electrode GT2. The second gate electrode GT2 and the second connection wiring TWL2-1 may be located on the fourth insulating layer 40 or 40-1 that is an insulating pattern. That is, the second gate electrode GT2 may be located on the first insulating pattern 40 and the second connection wiring TWL2-1 may be located on the second insulating pattern 40-1. The second insulating pattern 40-1 may be located between the fourth insulating layer 40 and the second connection wiring TWL2-1.

The second connection wiring TWL2-1 may be formed of the same material in the same process as the second gate electrode GT2. That is, to form the second connection wiring TWL2-1, a process other than the process of forming the second gate electrode GT2 is not required. Accordingly, the stacked structure of the display device DD (see FIG. 2) may be simplified. In addition, in manufacturing the display device DD (see FIG. 2), the process may be simplified by reducing the number of masks and processes required for the process. Meanwhile, each of the second gate electrode GT2 and the second connection wiring TWL2-1 may include a transparent conductive oxide. For example, each of the second gate electrode GT2 and the second connection wiring TWL2-1 may include indium tin oxide (ITO), indium zinc oxide (IZO), indium gallium zinc oxide (IGZO), zinc oxide (ZnO), or indium oxide (In₂O₃).

Aspects of some embodiments include a display device including first connection wiring and second connection wiring located on different layers. The first connection wiring is located on the same layer as the upper electrode overlapping the first gate electrode of the silicon semiconductor pattern, and the second connection wiring is located on the same layer as the oxide semiconductor pattern. The first connection wiring is formed of the same material in the same process as the upper electrode, and the second connection wiring is formed of the same material in the same process as the oxide semiconductor pattern. Accordingly, the display device may have a simple stacked structure. Also, the display device according to some embodiments may be manufactured without adding a mask or a process for forming the first connection wiring and the second connection wiring. Aspects of some embodiments include an electronic device including a display device having a simple stack structure and an electronic module.

A display device according to some embodiments may include a display device having a simplified stack structure by using one of metal layers included in transistors as a transparent electrode of a transmissive area. In addition, a display device having a simplified stack structure may be manufactured through a relatively simplified process.

In addition, the display device according to some embodiments may relatively efficiently arrange the wiring by doubly arranging the connection wiring on different layers in the transmissive area.

An electronic device according to some embodiments includes a display device and an electronic module having a relatively simplified stack structure, and thus may be manufactured through a relatively simplified process. In addition, the electronic device according to some embodiments may be capable of relatively efficiently arranging the wiring by doubly arranging the connection wiring on different layers in the transmissive area.

Although the embodiments of the inventive concept have been described, it is understood that the inventive concept should not be limited to these embodiments but various changes and modifications may be made by one ordinary skilled in the art within the spirit and scope of the inventive concept as hereinafter defined in the appended claims and their equivalents.

What is claimed is:

1. A display device comprising:
a display area including a first area and a second area adjacent to the first area; and
a display panel including a base layer including a peripheral area adjacent to the display area, an insulating layer disposed on the base layer, and a first pixel and a second pixel disposed on the base layer,
wherein the first pixel comprises a first sub-pixel and a second sub-pixel that are different from each other,
wherein the first sub-pixel comprises a first sub-light emitting element disposed in the first area and a first sub-pixel circuit electrically connected to the first sub-light emitting element,
wherein the second sub-pixel comprises a second sub-light emitting element disposed in the first area and a second sub-pixel circuit electrically connected to the second sub-light emitting element,
wherein the second pixel comprises a second light emitting element disposed in the second area and a second pixel circuit electrically connected to the second light emitting element and disposed in the second area,
wherein the first sub-pixel circuit comprises:
a first silicon transistor including a first silicon semiconductor pattern including a drain area, an active area, and a source area and a first gate electrode overlapping the active area of the first silicon semiconductor pattern, and disposed in the second area or the peripheral area;
a first oxide transistor including a first oxide semiconductor pattern including a drain area, an active area, and a source area and a second gate electrode overlapping the active area of the first oxide semiconductor pattern, and disposed in the second area or the peripheral area;
a first upper electrode overlapping the first gate electrode; and
a first connection wiring electrically connecting the first silicon transistor or the first oxide transistor and the first sub-light emitting element, overlapping the first area, disposed on a same layer as the first upper electrode, and including a transparent conductive oxide,
wherein the second sub-pixel circuit comprises:
a second silicon transistor including a second silicon semiconductor pattern including a drain area, an active area, and a source area and a third gate electrode overlapping the active area of the second silicon semiconductor pattern, and disposed in the second area or the peripheral area;
a second oxide transistor including a second oxide semiconductor pattern including a drain area, an active area, and a source area and a fourth gate electrode overlapping the active area of the second oxide semiconductor pattern, and disposed in the second area or the peripheral area;
a second upper electrode overlapping the third gate electrode; and
a second connection wiring electrically connecting the second silicon transistor or the second oxide transistor and the second sub-light emitting element, overlapping the first area, disposed on a same layer as the second oxide semiconductor pattern, and including a transparent conductive oxide.

2. The display device of claim 1, wherein the insulating layer comprises:
a lower insulating layer under the first upper electrode and the second upper electrode; and
an upper insulating layer on the first upper electrode and the second upper electrode.

3. The display device of claim 2, wherein the first and second oxide semiconductor patterns and the second connection wiring are disposed on the upper insulating layer.

4. The display device of claim 2, wherein the upper insulating layer covers the first connection wiring, the first upper electrode, and the second upper electrode.

5. The display device of claim 2, further comprising insulating patterns disposed between the active area of the first oxide semiconductor pattern and the second gate electrode and between the active area of the second oxide semiconductor pattern and the fourth gate electrode, respectively.

6. The display device of claim 2, wherein the insulating layer is disposed on the upper insulating layer and further comprises a cover insulating layer covering the first and second oxide semiconductor patterns and the second connection wiring.

7. The display device of claim 6, wherein the cover insulating layer has an opening corresponding to the first area,
wherein a portion of the second connection wiring is exposed by the opening defined in the cover insulating layer.

8. The display device of claim 1, wherein the first connection wiring, the second connection wiring, the first and second upper electrodes, and the first and second oxide semiconductor patterns each comprise at least one of In, Zn, and Sn.

9. The display device of claim 1, wherein the display area further comprises a third area adjacent to the second area,
wherein the display panel further comprises a third pixel disposed in the third area,
wherein the third pixel comprises a third light emitting element disposed in the third area and a third pixel circuit electrically connected to the third light emitting element and disposed in the third area,
wherein the number of second light emitting elements disposed per unit area of the second area is less than a number of third light emitting elements disposed per unit area of the third area,
wherein a sum of the numbers of the first sub-light emitting elements and the second sub-light emitting elements disposed per unit area of the first area is less than the number of third light emitting elements disposed per unit area of the third area.

10. The display device of claim 1, wherein an electrical conductivity of the second connection wiring is greater than an electrical conductivity of the active area of the first and second oxide semiconductor patterns.

11. A display device comprising:
a display area including a first area, a second area adjacent to the first area, and a third area adjacent to the second area; and
a display panel including a base layer including a peripheral area adjacent to the display area, an insulating layer disposed on the base layer, and first to third pixels disposed on the base layer,
wherein the first pixel comprises a first sub-pixel and a second sub-pixel that are different from each other,
wherein the first sub-pixel comprises a first sub-light emitting element disposed in the first area and a first sub-pixel circuit electrically connected to the first sub-light emitting element,
wherein the second sub-pixel comprises a second sub-light emitting element disposed in the first area and a second sub-pixel circuit electrically connected to the second sub-light emitting element,
wherein the second pixel comprises a second light emitting element disposed in the second area and a second pixel circuit electrically connected to the second light emitting element and disposed in the second area,
wherein the third pixel comprises a third light emitting element disposed in the third area and a third pixel circuit electrically connected to the third light emitting element,
wherein a sum of the numbers of the first sub-light emitting elements and the second sub-light emitting elements disposed per unit area of the first area is less than the number of the third light emitting elements disposed per unit area of the third area, wherein the number of second light emitting elements disposed per unit area in the second area is less than a number of third light emitting elements disposed per unit area in the third area,
wherein the first sub-pixel circuit comprises:
a first silicon transistor including a first silicon semiconductor pattern including a drain area, an active area, and a source area and a first gate electrode overlapping the active area of the first silicon semiconductor pattern, and disposed in the second area or the peripheral area;
a first oxide transistor including a first oxide semiconductor pattern including a drain area, an active area, and a source area and a second gate electrode overlapping the active area of the first oxide semiconductor pattern, and disposed in the second area or the peripheral area;
a first upper electrode overlapping the first gate electrode; and
a first connection wiring electrically connecting the first silicon transistor or the first oxide transistor and the first sub-light emitting element, overlapping the first area, disposed on a same layer as the first upper electrode, and including a transparent conductive oxide,
wherein the second sub-pixel circuit comprises:
a second silicon transistor including a second silicon semiconductor pattern including a drain area, an active area, and a source area and a third gate electrode overlapping the active area of the second silicon semiconductor pattern, and disposed in the second area or the peripheral area;
a second oxide transistor including a second oxide semiconductor pattern including a drain area, an active area, and a source area and a fourth gate electrode overlapping the active area of the second oxide semiconductor pattern, and disposed in the second area or the peripheral area;
a second upper electrode overlapping the third gate electrode; and
a second connection wiring electrically connecting the second silicon transistor or the second oxide transistor and the second sub-light emitting element, overlapping the first area, disposed on a layer different from the first connection wiring, and including a transparent conductive oxide

12. The display device of claim 11, wherein the insulating layer comprises:
a lower insulating layer under the first upper electrode and the second upper electrode; and
an upper insulating layer on the first upper electrode and the second upper electrode.

13. The display device of claim 12, wherein the first and second upper electrodes and the first and second oxide semiconductor patterns are disposed on a same layer on the lower insulating layer,
wherein the first and second upper electrodes and the first and second oxide semiconductor patterns are covered by the upper insulating layer.

14. The display device of claim 12, further comprising a first insulating pattern disposed between the active area of the first oxide semiconductor pattern and the second gate electrode and between the active area of the second oxide semiconductor pattern and the fourth gate electrode, and a second insulating pattern disposed between the lower insulating layer and the second connection wiring.

15. The display device of claim 14, wherein the first connection wiring, the second connection wiring, the first upper electrode, the second upper electrode, the first oxide semiconductor pattern, the second oxide semiconductor pattern, the second gate electrode, and the fourth gate electrode each comprises at least one of In, Zn, and Sn.

16. An electronic device comprising:
a display device including a sensing area configured to enable an optical signal to pass therethrough, a display area adjacent to the sensing area, and a peripheral area adjacent to the display area, wherein the sensing area comprises an element area overlapped by a first light emitting element including a first sub-light emitting element and a second sub-light emitting element, and a transmissive area non-overlapped by the first light emitting element; and
an electronic module disposed below the display device, overlapping the sensing area, and configured to receive the optical signal,
wherein the display device comprises:
a first sub-light emitting element disposed in the element area and a first sub-pixel circuit electrically connected to the first sub-light emitting element; and
a second sub-light emitting element disposed in the element area, and a second sub-pixel circuit electrically connected to the second sub-light emitting element,
wherein the first sub-pixel circuit comprises:
a first transistor including a first silicon semiconductor pattern including a drain area, an active area, and a source area and a first gate electrode overlapping the active area of the first silicon semiconductor pattern, and disposed in the display area or the peripheral area;
a second transistor including a first oxide semiconductor pattern including a drain area, an active area, and a source area and a second gate electrode overlapping the active area of the first oxide semiconductor pattern, and disposed in the display area or the peripheral area;
a first upper electrode overlapping the first gate electrode; and
a first connection wiring electrically connecting the first or second transistor and the first sub-light emitting element, overlapping the sensing area, and disposed on a same layer as the first upper electrode, and including a transparent conductive oxide,
wherein the second sub-pixel circuit comprises:
a third transistor including a second silicon semiconductor pattern including a drain area, an active area, and a source area and a third gate electrode overlapping the active area of the second silicon semiconductor pattern, and disposed in the display area or the peripheral area;
a fourth transistor including a second oxide semiconductor pattern including a drain area, an active area, and a source area and a fourth gate electrode overlapping the active area of the second oxide semiconductor pattern, and disposed in the display area or the peripheral area;
a second upper electrode overlapping the third gate electrode; and
a second connection wiring electrically connecting the third transistor or the fourth transistor and the second sub-light emitting element, overlapping the sensing area and disposed on a same layer as the second oxide semiconductor pattern, and including a transparent conductive oxide.

17. The electronic device of claim 16, wherein the display device further comprises a display pixel including a second light emitting element disposed in the display area and a second pixel circuit electrically connected to the second light emitting element and disposed in the display area,
wherein a sum of the numbers of the first sub-light emitting elements and the second sub-light emitting elements per unit area disposed in the sensing area is less than the number of second light emitting elements disposed per unit area in the display area.

18. The electronic device of claim 16, wherein the electronic module comprises a camera module.

19. The electronic device of claim 16, wherein an electrical conductivity of the second connection wiring is greater than each electrical conductivity of the active area of the first oxide semiconductor pattern and the active area of the second oxide semiconductor pattern.

20. The electronic device of claim 16, wherein the display device further comprises a window,
wherein the window comprises a base film and a bezel pattern disposed on the base film and overlapping the peripheral area.
